(19) United States
(12) Patent Application Publication
(10) Pub. No.: US 2023/0010155 A1
(43) Pub. Date: Jan. 12, 2023

(54) TIME CORRECTION APPARATUS, TIME CORRECTION METHOD, AND COMPUTER READABLE MEDIUM

(71) Applicant: MITSUBISHI ELECTRIC CORPORATION, Tokyo (JP)

(72) Inventor: Taichi SAKAUE, Tokyo (JP)

(73) Assignee: MITSUBISHI ELECTRIC CORPORATION, Tokyo (JP)

(21) Appl. No.: 17/952,585

(22) Filed: Sep. 26, 2022

Related U.S. Application Data
(63) Continuation of application No. PCT/JP2020/021347, filed on May 29, 2020.

(51) Int. Cl. H04L 7/00

(52) U.S. Cl. CPC H04L 7/0016

(57) ABSTRACT

A frequency deviation change rate computation unit (204) computes a frequency deviation change rate being a change rate per unit time of a frequency deviation between a clock frequency of a synchronization reference device serving as a reference of time synchronization and a clock frequency of a time synchronization device which performs time synchronization with the synchronization reference device. A time correction amount computation unit (205) computes a first correction amount corresponding to a static frequency deviation between the clock frequency of the synchronization reference device and the clock frequency of the time synchronization device, performs time integration of the frequency deviation change rate to compute a second correction amount corresponding to temporal transition of the frequency deviation between the clock frequency of the synchronization reference device and the clock frequency of the time synchronization device, and computes a time correction amount for correcting a time of the time synchronization device with using the first correction amount and the second correction amount. A time correction unit (206) corrects the time of the time synchronization device with using the time correction amount.

### CROSS REFERENCE TO RELATED APPLICATIONS

This application is a Continuation of PCT International Application No. PCT/JP2020/021347, filed on May 29, 2020, which is hereby expressly incorporated by reference into the present application.

### TECHNICAL FIELD

The present disclosure relates to time synchronization.

### BACKGROUND ART

In recent years, application of TSN (Time Sensitive Networking) to FA (Factory Automation) networks has been studied. In TSN, time division communications are carried out using a time synchronization protocol standardized in IEEE802.1AS or IEEE1588 (hereinafter, sometimes referred to just as protocol). To ensure the real-time nature of an FA network, it is necessary to achieve synchronization accuracy with ±1 μs. Factors that dictate synchronization accuracy include jitter in propagation time of frames that deliver time distribution and frequency deviations of crystal oscillators in individual devices. Factors of the frequency deviation of a crystal oscillator include deviation of frequency specific to the crystal oscillator and a change in frequency caused by temperature change. Due to these factors, there are cases where sufficient synchronization accuracy cannot be guaranteed.

In a case where a very large number of devices across which time synchronization is performed are present in a network, meeting sufficient synchronization accuracy requires reducing both the factors: the influence of jitter in frame propagation time and a time discrepancy due to frequency change. However, in an environment with significant frequency changes (an environment with significant temperature changes, such as in a thermostatic chamber test), increasing of the number of averaging leads to degraded synchronization performance conversely. To achieve sufficient synchronization accuracy, it is necessary not only to reduce the influence of jitter but also to correct a time discrepancy due to frequency deviation.

Patent Literature 1 discloses a technique for correcting a time discrepancy due to frequency deviation.

### CITATION LIST

### Patent Literature

Patent Literature 1: JP 2017-188876

### SUMMARY OF INVENTION

### Technical Problem

Patent Literature 1 only discloses a technique to correct a time discrepancy due to frequency deviation when frequency deviation is constant. That is, the technique of Patent Literature 1 has a problem of being unable to perform time correction in accordance with varying frequency deviation when the frequency deviation varies.

One major object of the present disclosure is to solve such a problem. More specifically, one major object of the present disclosure is to enable time correction in accordance with varying frequency deviation when the frequency deviation varies.

### Solution to Problem

A time correction apparatus according to the present disclosure, includes:

a frequency deviation change rate computation unit to compute a frequency deviation change rate being a change rate per unit time of a frequency deviation between a clock frequency of a synchronization reference device serving as a reference of time synchronization and a clock frequency of a time synchronization device which performs time synchronization with the synchronization reference device;

a time correction amount computation unit to compute a first correction amount corresponding to a static frequency deviation between the clock frequency of the synchronization reference device and the clock frequency of the time synchronization device, to perform time integration of the frequency deviation change rate to compute a second correction amount corresponding to temporal transition of the frequency deviation between the clock frequency of the synchronization reference device and the clock frequency of the time synchronization device, and to compute a time correction amount for correcting a time of the time synchronization device with using the first correction amount and the second correction amount; and

a time correction unit to correct the time of the time synchronization device with using the time correction amount.

### Advantageous Effects of Invention

The present disclosure enables time correction in accordance with varying frequency deviation when the frequency deviation varies.

### BRIEF DESCRIPTION OF DRAWINGS

FIG. 1 illustrates a configuration example of a time synchronization system according to Embodiment 1.

FIG. 2 illustrates a hardware configuration example of a slave device according to Embodiment 1.

FIG. 3 illustrates a functional configuration example of the slave device according to Embodiment 1.

FIG. 4 is a flowchart illustrating an operation example of the slave device according to Embodiment 1.

FIG. 5 illustrates a specific example of a time correction method according to Embodiment 1.

FIG. 6 illustrates a functional configuration example of a slave device according to Embodiment 2.

FIG. 7 illustrates an internal configuration example of a learning unit for implementing a time correction method (2-a) according to Embodiment 2.

FIG. 8 is a flowchart illustrating an operation example of the slave device for implementing the time correction method (2-a) according to Embodiment 2.

FIG. 9 illustrates a specific example of a time correction method (2-a) according to Embodiment 2.

FIG. 10 illustrates an internal configuration example of the learning unit for implementing a time correction method (2-b) according to Embodiment 2.

FIG. 11 is a flowchart illustrating an operation example of the slave device for implementing the time correction method (2-b) according to Embodiment 2.

FIG. 12 illustrates a specific example of the time correction method (2-b) according to Embodiment 2.

FIG. 13 illustrates an example of frequency deviation characteristics of a crystal oscillator according to Embodiment 3.

FIG. 14 illustrates a relation among a deviation temperature characteristics estimation unit, a deviation temporal characteristics estimation unit, and a time correction amount estimation unit according to Embodiment 3.

FIG. 15 illustrates an internal configuration example of a learning unit for implementing a time correction method (3-a) according to Embodiment 3.

FIG. 16 illustrates an internal configuration example of the learning unit for implementing a time correction method (3-b) according to Embodiment 3.

FIG. 17 illustrates estimation of a time correction amount according to Embodiment 3.

FIG. 18 illustrates an example of sign detection (3-a) according to Embodiment 3.

FIG. 19 illustrates an example of sign detection (3-b) according to Embodiment 3.

FIG. 20 illustrates a method of calculating a time correction amount according to Embodiment 3.

FIG. 21 illustrates a method of calculating a time correction amount by means of small time according to Embodiment 3.

FIG. 22 illustrates a time correction method in an example (3-a) of sign detection according to Embodiment 3.

FIG. 23 illustrates a time correction method in an example (3-b) of sign detection according to Embodiment 3.

FIG. 24 illustrates a functional configuration example of a slave device according to Embodiment 4.

FIG. 25 illustrates a configuration example of a time synchronization system according to Embodiment 5.

FIG. 26 illustrates a functional configuration example of a slave device according to Embodiment 5.

FIG. 27 illustrates a functional configuration example of a server device according to Embodiment 5.

FIG. 28 illustrates the principle of time synchronization of IEEE802.1AS.

### DESCRIPTION OF EMBODIMENTS

Embodiments are described below with drawings. In the description of embodiments below and drawings, portions given the same reference characters indicate the same or equivalent portions.

### Embodiment 1

***Time Synchronization of IEEE802.1AS***

Before describing the present embodiment, the principle of time synchronization of IEEE802.1AS, which underlies the embodiment, is described.

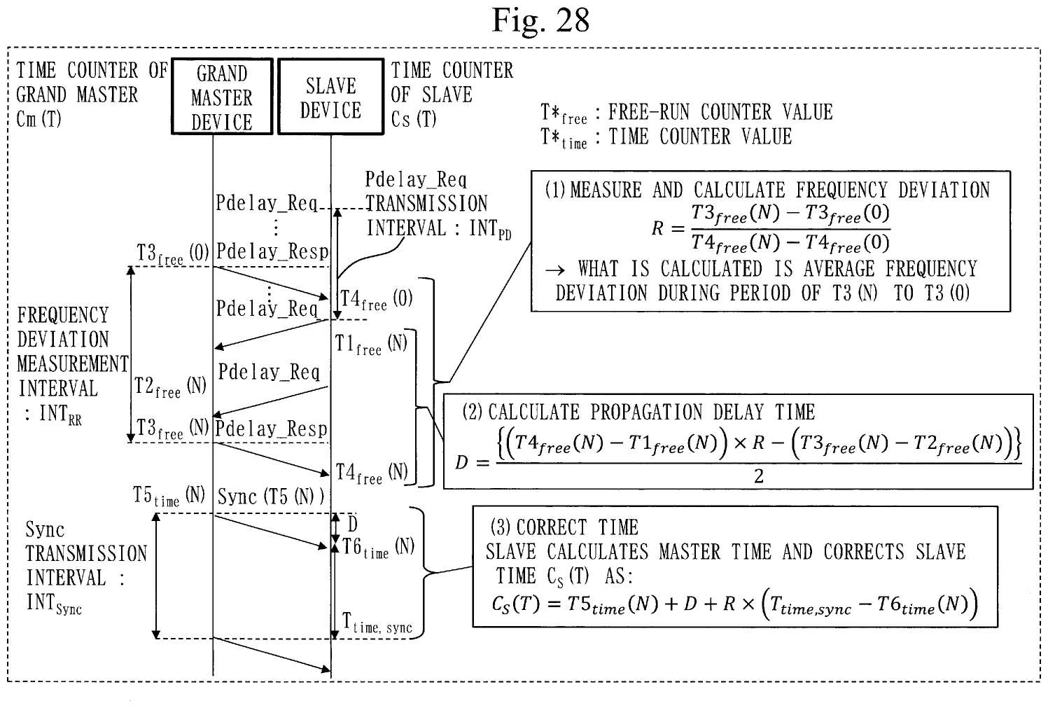

FIG. 28 shows a communication sequence for the time synchronization of IEEE802.1AS.

The example of FIG. 28 describes an instance where a slave device is synchronized with the time of a grand master device.

The grand master device and the slave device each implement two kinds of counter: a time counter and a free-run counter.

A counter value of the time counter is corrected to the time of the grand master device.

The free-run counter is a counter that keeps freely running without being corrected.

On the slave device, time is kept by the free-run counter. The slave device then advances the count of the time counter based on the value of the free-run counter. The time counter of the slave device is regularly corrected to the time of the grand master device (the value of its time counter).

In the following, the value of the free-run counter will be represented as T*_{free} and the value of the time counter will be represented as T*ₜᵢₘₑ.

In time synchronization, the processes (1), (2), and (3) below are performed.

(1) Calculation of Frequency Deviation

(a) The slave device transmits a Pdelay_Req frame to the grand master device. The grand master device transmits a Pdelay_Resp frame to the slave device as a response to the Pdelay_Req frame. The grand master device retrieves a timestamp (T3_{free}(0)) at the time of transmission of the Pdelay_Resp frame.

(b) The slave device receives the Pdelay_Resp frame. The slave device also retrieves a timestamp (T4_{free}(0)) at the time of reception of the Pdelay_Resp frame.

(c) Next, the grand master device stores timestamp information for T3_{free}(0) in a PdelayResp_Follow_Up frame and transmits the PdelayResp_Follow_Up frame to the slave device (in FIG. 28, illustration of transmission of PdelayResp_Follow_Up frame is omitted).

(d) From a timestamp (T3_{free}(N)) at the time of transmission of the Pdelay_Resp frame and a timestamp (T4_{free}(N)) at the time of its reception N intervals after (a), the slave device calculates a frequency deviation R according to expression 1 below (strictly speaking, R is a frequency deviation ratio, defined as Rate Ratio in IEEE802.1AS).

[FORMULA 1]

$$R = \frac{{T 3}_{free} ( N ) - {T 3}_{free} ( 0 )}{{T 4}_{free} ( N ) - {T 4}_{free} ( 0 )} \qquad expression 1$$

(2) Calculation of Propagation Delay Time

(a) The slave device transmits a Pdelay_Req frame and retrieves a timestamp (T1_{free}(N)) at the time of transmission of the Pdelay_Req frame.

(b) The grand master device receives the Pdelay_Req frame and retrieves a timestamp (T2_{free}(N)) at the time of reception of the Pdelay_Req frame.

(c) The grand master device stores the timestamp (T2_{free}(N)) at the time of reception of the Pdelay_Req frame in a Pdelay_Resp frame and transmits the Pdelay_Resp frame to the slave device. At this point, the grand master device retrieves a timestamp (T3_{free}(N)) at the time of transmission of the Pdelay_Resp frame.

(d) The slave device receives the Pdelay_Resp frame and retrieves a timestamp (T4_{free}(N)) at the time of reception of the Pdelay_Resp frame.

(e) The grand master device stores the timestamp information for T3_{free}(N) in a Pdelay_Resp_Follow_Up frame and transmits the Pdelay_Resp_Follow_Up frame to the slave device (in FIG. 28, illustration of transmission of PdelayResp_Follow_Up frame is omitted).

(f) The slave device receives the Pdelay_Resp_Follow_Up frame and retrieves the timestamp information for T3_{free}(N).

(g) The slave device calculates a propagation delay time D according to expression 2 below.

[FORMULA 2]

$$D = \frac{\{ ( T {4}_{free} ( N ) - T {1}_{free} ( N ) ) ⨯ R - ( T {3}_{free} ( N ) - {T 2}_{free} ( N ) ) \}}{2} \qquad expression 2$$

(3) Time Correction

(a) The grand master device transmits a Sync frame and retrieves a timestamp (T5ₜᵢₘₑ(N)) at the time of transmission of the Sync frame.

(b) The slave device receives the Sync frame and retrieves a timestamp (T6ₜᵢₘₑ(N)) at the time of reception of the Sync frame.

(c) The grand master device stores timestamp information for T5ₜᵢₘₑ(N) in a Follow_Up frame and transmits the Follow_Up frame to the slave device (in FIG. 28, illustration of transmission of Follow_Up frame is omitted).

(d) The slave device receives the Follow_Up frame and retrieves the timestamp information for T5ₜᵢₘₑ(N).

(e) After receiving the Sync frame, the slave device calculates time Cs(T) on the grand master device at time T_{time,sync}, at which time synchronization is performed, according to expression 3 below and corrects its time to Cs(T) at time T_{time,sync}.

[FORMULA 3]

Cs(T)=T5ₜᵢₘₑ(N)+D+Rx(T_{time,sync}−T6ₜᵢₘₑ(N)) expression 3

A time discrepancy between the grand master device and the slave device is primarily caused by “D+R×(T_{time,sync}−T6ₜᵢₘₑ(N))” in expression 3. That is to say, a discrepancy of time occurs while the slave device is freely running.

Frequency deviation is calculated using the timestamps corresponding to N intervals (N being an integer 1) which are obtained in the Pdelay_Req frame and Pdelay_Resp frame. Accordingly, in FIG. 28, frequency deviation measurement interval INT_{RR} is an integer multiple of Pdelay_Req transmission interval INT_{PD}.

INT_{RR}=INT_{PD}×N (N being an integer≥1)

The relationship of magnitude between Pdelay_Req transmission interval INT_{PD} and Sync transmission interval INT_{sync} is not specifically prescribed in the standards. While INT_{PD}=INT_{sync} is assumed in the present embodiment, the relationship of magnitude between INT_{PD} and INT_{sync} does not matter.

Frequency deviation calculation interval, to be discussed later, is assumed to be of an equivalent length to Pdelay_Req transmission interval INT_{PD}. The frequency deviation calculation interval is not defined in the standards.

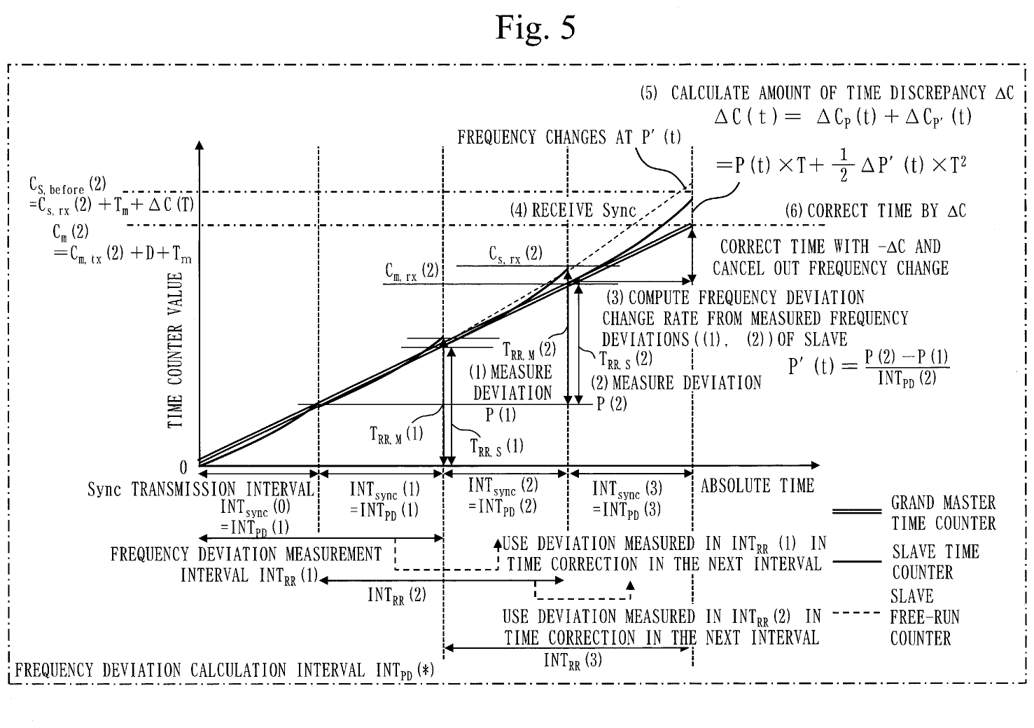

The relationship between the frequency deviation measurement interval and the frequency calculation interval is as shown in FIG. 5. Timestamps for use in frequency deviation measurement are obtained at Pdelay_Req transmission intervals and a frequency deviation is calculated with the latest value and the timestamp N intervals ago. Thus, the frequency deviation itself is calculated at every Pdelay_Req transmission interval (the frequency deviation calculation interval).

***Description of Configuration***

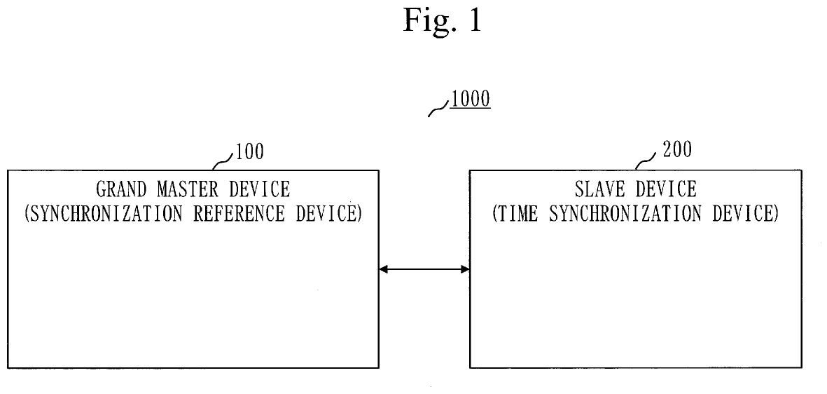

FIG. 1 shows an example of a time synchronization system 1000 according to the present embodiment.

The time synchronization system 1000 according to the present embodiment is formed of a grand master device 100 and a slave device 200.

The grand master device 100 serves as a reference of time synchronization. The grand master device 100 performs time distribution. The grand master device 100 corresponds to a synchronization reference device.

The slave device 200 performs time synchronization with the grand master device 100. The slave device 200 corresponds to a time synchronization device.

The grand master device 100 is a computer. Specifically, the grand master device 100 may be a switch dedicated for time synchronization, a terminal dedicated for time synchronization, an IC (Integrated Circuit) chip dedicated for time synchronization, or a device not intended for control, such as a general-purpose PC (Personal Computer). The grand master device 100 may also be a controller such as a PLC (Programmable Logic Controller) and a motion controller.

The slave device 200 is also a computer. Specifically, the slave device 200 may be a switch dedicated for time synchronization, a terminal dedicated for time synchronization, an IC chip dedicated for time synchronization, or a device not intended for control, such as a general-purpose PC. The slave device 200 may also be a controller such as a PLC and a motion controller.

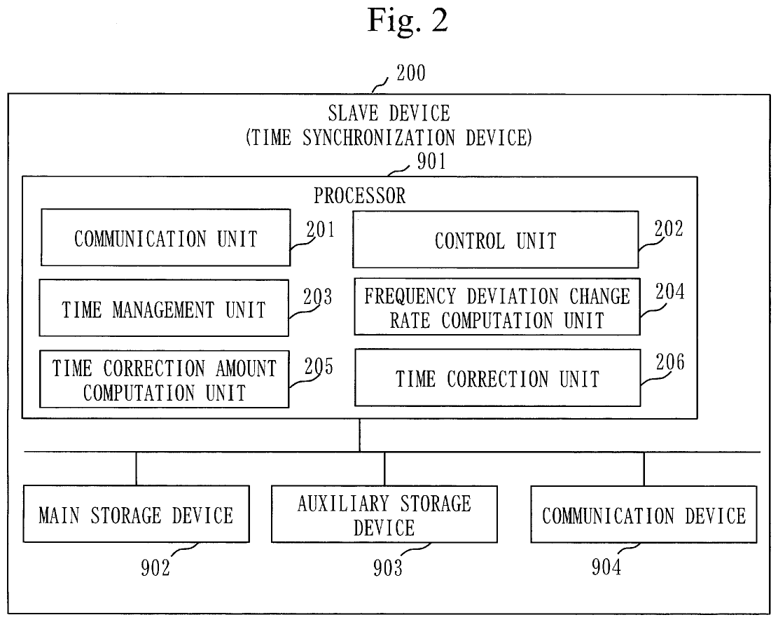

FIG. 2 shows a hardware configuration example of the slave device 200.

The slave device 200 includes a processor 901, a main storage device 902, an auxiliary storage device 903, and a communication device 904 as pieces of hardware.

The slave device 200 also includes a communication unit 201, a control unit 202, a time management unit 203, a frequency deviation change rate computation unit 204, a time correction amount computation unit 205, and a time correction unit 206, discussed later, as functional components.

The auxiliary storage device 903 has stored therein programs for implementing the functions of the communication unit 201, the control unit 202, the time management unit 203, the frequency deviation change rate computation unit 204, the time correction amount computation unit 205, and the time correction unit 206.

These programs are loaded from the auxiliary storage device 903 to the main storage device 902. Then, the processor 901 executes the programs to perform the operations of the communication unit 201, the control unit 202, the time management unit 203, the frequency deviation change rate computation unit 204, the time correction amount computation unit 205, and the time correction unit 206 as discussed later.

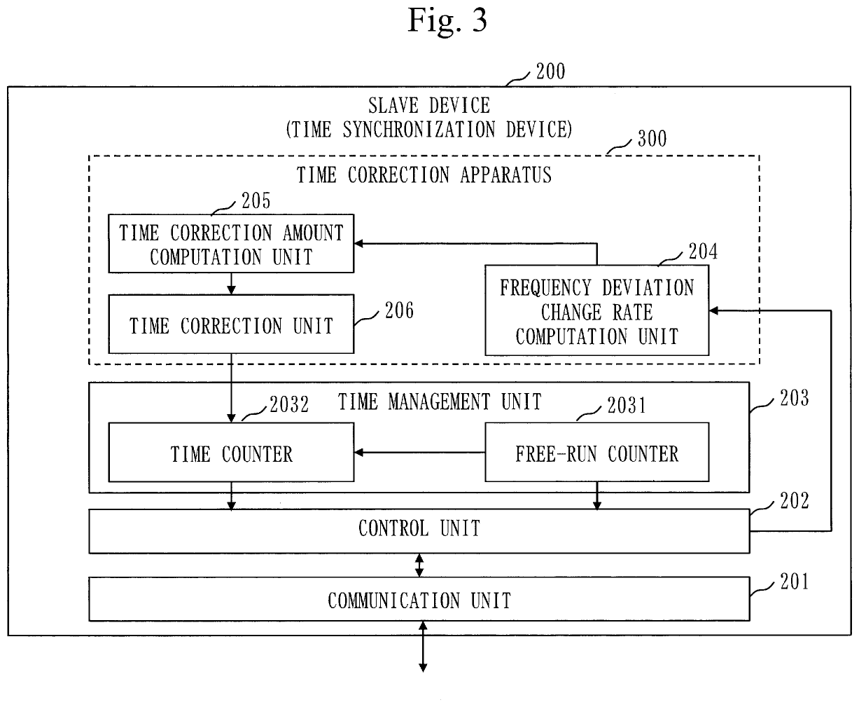

FIG. 3 schematically represents a situation where the processor 901 is executing the programs for implementing the functions of the communication unit 201, the control unit 202, the time management unit 203, the frequency deviation change rate computation unit 204, the time correction amount computation unit 205, and the time correction unit 206.

FIG. 3 shows a functional configuration example of the slave device 200 according to the present embodiment.

The communication unit 201 uses the communication device 904 to perform transmission and reception of communication frames as described with FIG. 28, such as transmission of Pdelay_Req frame and reception of Pdelay_Resp frame. Communication frames that are used for time synchronization, described with FIG. 28, are called time synchronization frames.

The control unit 202 controls the operation of the slave device 200. Specifically, the control unit 202 generates time synchronization frames to be transmitted to the grand master device 100, such as Pdelay_Req frame. The control unit 202 also processes time synchronization frames received from the grand master device 100, such as Pdelay_Resp frame. Further, the control unit 202 performs management of timestamps.

The time management unit 203 manages a free-run counter 2031 and a time counter 2032.

The free-run counter 2031 and the time counter 2032 are similar to those described in FIG. 28.

The frequency deviation change rate computation unit 204 computes a frequency deviation and a frequency deviation change rate. The frequency deviation change rate is the rate of change in the frequency deviation per unit time. This frequency deviation is a deviation between the clock frequency of the grand master device 100 and the clock frequency of the slave device 200.

Processing performed by the frequency deviation change rate computation unit 204 corresponds to a frequency deviation change rate computation process.

The time correction amount computation unit 205 performs time integration of the frequency deviation to compute a time correction amount for correcting the time of the slave device 200. That is, the time correction amount computation unit 205 computes a time correction amount for correcting the value of the time counter 2032.

Processing performed by the time correction amount computation unit 205 corresponds to a time correction amount computation process.

The time correction unit 206 corrects the time of the slave device 200 using the time correction amount computed by the time correction amount computation unit 205. More specifically, the time correction unit 206 corrects the time of the slave device 200 by subtracting the time correction amount from the counter value of the time counter 2032, which is an internal time of the slave device 200.

Processing performed by the time correction unit 206 corresponds to a time correction process.

The frequency deviation change rate computation unit 204, the time correction amount computation unit 205, and the time correction unit 206 constitute a time correction apparatus 300.

An operation procedure of the time correction apparatus 300 corresponds to a time correction method. A program that implements the operations of the time correction apparatus 300 corresponds to a time correction program.

***Description of Operation***

In the present embodiment, the frequency deviation change rate computation unit 204 regularly computes the frequency deviation between the clock frequency of the grand master device 100 and the clock frequency of the slave device 200 and also regularly computes the frequency deviation change rate. In the present embodiment, the time correction amount computation unit 205 computes a time correction amount for correcting a time discrepancy due to frequency change, as a time-integrated value of the frequency deviation change rate. Then, the time correction unit 206 performs time correction using the time correction amount.

(A) Computation of Frequency Deviation Change Rate

The frequency deviation change rate computation unit 204 computes a frequency deviation using the protocol of IEEE1588 or IEEE802.1AS and stores the computed value of frequency deviation in the main storage device 902 or the auxiliary storage device 903. The frequency deviation change rate computation unit 204 also computes the frequency deviation change rate from the past frequency deviation N intervals ago.

(B) Correction of Time

The frequency deviation change rate can be represented in the unit of ppm/s. Given frequency deviation change rate P′(s) [ppm/s], the value of the time counter 2032 after elapse of an absolute time of t seconds can be represented by a time integration of P′(t)×t, as in expression 4 below.

[FORMULA 4]

$$Δ {C}_{{p}^{′}} ( t ) = \int {P}^{′} ( t ) ⨯ t dt ≅ \frac{1}{2} ⨯ {P}^{′} ( t ) ⨯ {t}^{2} [ s ] \qquad expression 4$$

The approximation expression in expression 4 (½×P′(t)×t²) is an approximation in a section in which the frequency change can be considered as monotonous increase.

In the present embodiment, the frequency change can be considered as monotonous increase. Accordingly, the time correction amount computation unit 205 computes a correction amount ΔC_{p′}(t) corresponding to the temporal transition of the frequency deviation between the grand master device 100 and the slave device 200 according to expression 5 below, using an elapsed time T from the time of Sync reception (or alternatively, average Sync reception time), in addition to a correction amount for correcting time discrepancy caused by static deviation. The correction amount ΔC_{p′}(t) corresponds to a second correction amount. Although, for simplification of calculation, an example of computing the second correction amount by expression 5 is shown here, if the frequency change cannot be considered to be monotonous increase, the time correction amount computation unit 205 computes the correction amount ΔC_{p′}(t) by performing time integration of the frequency deviation change rate as shown in expression 4. The time correction amount computation unit 205 may also compute the correction amount ΔC_{p′}(t) by performing time integration of the frequency deviation change rate as shown in expression 4 even when the frequency change can be considered to be monotonous increase, in order to perform accurate time correction.

[FORMULA 5]

$$Δ {C}_{{p}^{′}} ( t ) = \frac{1}{2} {P}^{′} ( t ) ⨯ {T}^{2} [ s ] \qquad expression 5$$

Next, an operation example of the slave device 200 according to the present embodiment is described in more detail.

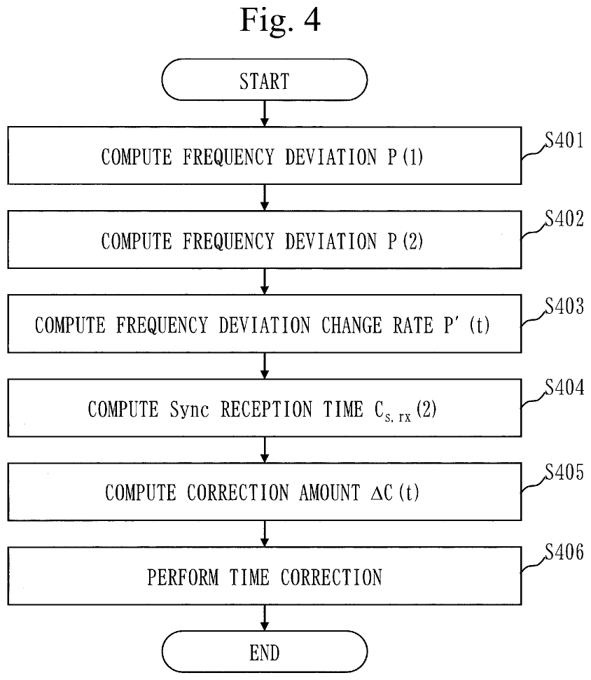

FIG. 4 shows an operation example of the slave device 200 according to the present embodiment. FIG. 5 shows a specific example of the time correction method according to the present embodiment.

First, the frequency deviation change rate computation unit 204 computes a frequency deviation P(1) (step S401).

More specifically, the frequency deviation change rate computation unit 204 computes the frequency deviation P(1) between the clock frequency of the grand master device 100 and that of the slave device 200, according to expression 6, in the section of frequency deviation measurement interval INT_{RR}(1) shown in FIG. 5.

Here, the frequency deviation change rate computation unit 204 computes T_{RR,M}(1) and T_{RR,S}(1) in expression 6 according to the same procedure as that described with reference to FIG. 28, for example.

T_{RR,M}(1) is an amount of time equivalent to INT_{RR}(1) as measured by the grand master device 100, and T_{RR,S}(1) is an amount of time equivalent to INT_{RR}(1) as measured by the slave device 200. With the expression below, a ratio of passage of time between the grand master device 100 and the slave device 200 is determined.

[FORMULA 6]

$$P ( 1 ) = \frac{{T}_{RR , M} ( 1 )}{{T}_{RR , S} ( 1 )} \qquad expression 6$$

Next, the frequency deviation change rate computation unit 204 computes a frequency deviation P(2) (step S402).

That is, the frequency deviation change rate computation unit 204 computes the frequency deviation P(2) between the clock frequency of the grand master device 100 and that of the slave device 200, according to expression 7, in the section of frequency deviation measurement interval INT_{RR}(2) shown in FIG. 5.

As with the case of expression 6, the frequency deviation change rate computation unit 204 computes T_{RR,M}(2) and T_{RR,S}(2) in expression 7 according to the same procedure as that described with reference to FIG. 28, for example.

T_{RR,M}(2) is an amount of time equivalent to INT_{RR}(2) as measured by the master, and T_{RR,S}(2) is an amount of time equivalent to INT_{RR}(2) as measured by the slave.

[FORMULA 7]

$$P ( 2 ) = \frac{{T}_{RR , M} ( 2 )}{{T}_{RR , S} ( 2 )} \qquad expression 7$$

Next, the frequency deviation change rate computation unit 204 computes the frequency deviation change rate P′(t) according to expression 8 using the frequency deviation P(1) computed at step S401 and the frequency deviation P(2) computed at step S402 (step S403).

As shown in FIG. 5, the frequency deviation calculation interval is INT_{PD}(*) (=INT_{Sync}(*)). The frequency deviation calculation interval INT_{PD}(*) serves as the Pdelay_Req transmission interval as well. INT_{Sync}(*) is the Sync transmission interval, as shown in FIG. 28. The Sync transmission interval corresponds to the time synchronization frame transmission interval.

[FORMULA 8]

$${P}^{′} ( t ) = \frac{P ( 2 ) - P ( 1 )}{{INT}_{PD} ( 2 )} \qquad expression 8$$

Next, the frequency deviation change rate computation unit 204 computes Sync reception time C_{s,rx}(2) (step S404).

Specifically, the communication unit 201 receives a Sync frame, which is a time distribution frame, from the grand master device 100. Then, the frequency deviation change rate computation unit 204 computes Sync reception time C_{s,rx}(2) according to expression 9 based on the time of transmission of the Sync frame at the grand master device 100 indicated in the Sync frame.

In expression 9, D represents propagation delay time, and C_{m,tx}(2) is the time of transmission of the Sync frame at the grand master device 100 indicated in the Sync frame.

[FORMULA 9]

C_{s,rx}(2)=C_{m,tx}(2)+D expression 9

Next, the time correction amount computation unit 205 computes a time correction amount ΔC(t) (step S405).

Specifically, the time correction amount computation unit 205 computes ΔCₚ(t) according to expression 10. The time correction amount computation unit 205 further computes ΔC_{p′}(t) according to expression 5. ΔCₚ(t) is a correction amount corresponding to a time discrepancy due to static frequency deviation between the grand master device 100 and the slave device 200. ΔCₚ(t) corresponds to a first correction amount. As mentioned earlier, ΔC_{p′}(t) is a correction amount for correcting time discrepancy due to frequency change, corresponding to the second correction amount. ΔC_{p′}(t) is obtained by expression 5.

Then, the time correction amount computation unit 205 adds ΔCₚ(t) and ΔC_{p′}(t) as shown in expression 11 to compute a time correction amount ΔC(t) for finally correcting the time counter 2032. The time correction amount ΔC(t) is a value for correcting the amount of time discrepancy from the reception of Sync frame to the time correction in step S406, which is discussed later.

The frequency deviation change rate computation unit 204 computes the frequency deviation change rate in accordance with the Sync transmission interval which is the time synchronization frame transmission interval. The time correction amount computation unit 205 computes ΔCₚ(t) and ΔC_{p′}(t) in accordance with the Sync transmission interval. Then, the time correction amount computation unit 205 computes the time correction amount ΔC(t) for the current Sync transmission interval, using ΔCₚ(t) and ΔC_{p′}(t) that were computed in the Sync transmission interval immediately preceding the current Sync transmission interval.

[FORMULA 10]

ΔCₚ(t)=P(2)×T expression 10

[FORMULA 11]

ΔC(t)=ΔCₚ(t)+ΔC_{p′}(t) expression 11

Finally, the time correction unit 206 performs time correction using the correction amount ΔC(t) (step S406).

Specifically, the time correction unit 206 corrects the counter value of the time counter 2032 using the correction amount ΔC(t) in the following manner.

The time of the slave device 200 before correction, C_{S,before}(2), can be represented by expression 12 below. Here, Tₘ is the counter value of the free-run counter of the grand master device 100, corresponding to the amount of time from when the grand master device 100 transmits a Sync frame to when the time correction unit 206 performs time synchronization.

[FORMULA 12]

C_{S,before}(2)=C_{s,rx}(2)+Tₘ+ΔC(t) expression 12

From expressions 9 and 11, the time counter 2032 can be synchronized with the time counter of the grand master device 100 by subtracting the value of the time correction amount ΔC(t) from the time C_{S,before}(2) after T [s] at the time counter 2032 by the time correction unit 206, as shown in expression 13.

In expression 13, C_{S,after}(2) is the counter value of the time counter 2032 upon time synchronization. In expression 13, Cₘ(2) is the counter value of the time counter of the grand master device 100 to which the time correction unit 206 needs to perform time synchronization.

[FORMULA 13]

$$\begin{matrix}Cs {,}_{after} ( 2 ) = Cs {,}_{before} ( 2 ) - Δ C ( T ) \\ = {C}_{m , tx} ( 2 ) + D + {T}_{m} + Δ C ( T ) - Δ C ( T ) \\ = {C}_{m , tx} ( 2 ) + D + {T}_{m} \\ ≅ {C}_{m} ( 2 )\end{matrix} \qquad expression 13$$

***Description of Effects of the Embodiment***

According to the present embodiment, time correction in accordance with varying frequency deviation is possible when the frequency deviation varies. Thus, according to the present embodiment, the influence of frequency change can be reduced even in an environment with significant frequency change. Moreover, according to the present embodiment, reducing the influence of frequency change enables the number of jitter averaging to be increased. Thus, time discrepancy due to jitter can be reduced as well.

In a large network with many slave devices connected, it is considered that time discrepancy due to the influence of frequency change and time discrepancy due to jitter can accumulate. According to the present embodiment, time synchronization with high accuracy can be achieved even in such a large network by reducing the influence of frequency change.

While the present embodiment describes an example where the time correction apparatus 300 is present on the slave device 200, the time correction apparatus 300 is present also at the grand master device 100.

At the startup of the time synchronization system 1000, a node to act as the grand master device 100 is determined by arbitration, so which node is to act as the grand master device 100 is uncertain until the arbitration converges. For this reason, the time correction apparatus 300 is present not only at a node that acts as the slave device 200 but at anode that acts as the grand master device 100. In a period until when the node to act as the grand master device 100 is designated as the grand master device 100, frequency deviation at that node can be corrected by the time correction apparatus 300.

### Embodiment 2

In the present embodiment, an example is described, where the temporal transition of the frequency deviation change rate is machine-learned by means of AI (Artificial Intelligence) and time correction is performed based on the result of machine learning.

In the present embodiment, mainly differences from Embodiment 1 are discussed.

Matters that are not discussed below are similar to Embodiment 1. For example, in the present embodiment, an exemplary configuration of the time synchronization system 1000 is also as shown in FIG. 1.

Temporal change of the frequency deviation can be predicted from an operating environment of the slave device 200. For example, in a case where the slave device 200 operates in an ordinary temperature environment (when no control that causes heating of the slave device 200 is performed either), temperature change is minute and the state of the slave device 200 is stable. In contrast, at the startup of the slave device 200, the temperature of the crystal oscillator monotonously increases. In the former operating environment, sufficient time synchronization can be achieved with the time synchronization protocol of IEEE802.1AS or IEEE1588. In the latter operating environment, however, it is difficult to perform sufficient time synchronization with the time synchronization protocol of IEEE802.1AS or IEEE1588.

In addition, in an operation environment that involves a sharp rise or drop in temperature, frequency deviation also increases or decreases sharply.

The phenomenon of sharp rise or drop in temperature can presumably result from control on an installation or equipment. If a sharp rise or drop in temperature is caused by control on an installation or equipment, the phenomenon of a sharp rise or drop in temperature can be expected to occur periodically. Alternatively, it can be expected that a sharp rise or drop in temperature occurs starting at a certain control operation.

Thus, the slave device 200 according to the present embodiment uses a neural network to learn the periodicity of frequency deviation or a sign of a sharp variation in frequency and further learns correction amounts for time correction.

In the present embodiment, the slave device 200 performs either “(2-a) a method of time correction by detecting the temporal periodicity of frequency deviation” and “(2-b) a method of time correction by detecting a feature amount of the temporal transition of frequency deviation” as a machine learning method. In the following, the “(2-a) method of time correction by detecting the temporal periodicity of frequency deviation” will be referred to as time correction method (2-a). The “(2-b) method of time correction by detecting a feature amount of the temporal transition of frequency deviation” will be referred to as time correction method (2-b).

In both the time correction method (2-a) and time correction method (2-b), time synchronization AI incorporated in the slave device 200 learns characteristics of frequency deviation and computes time correction amounts in a learning phase. The slave device 200 performs time correction with the time correction amount resulting from the learning of the time synchronization AI in an application phase.

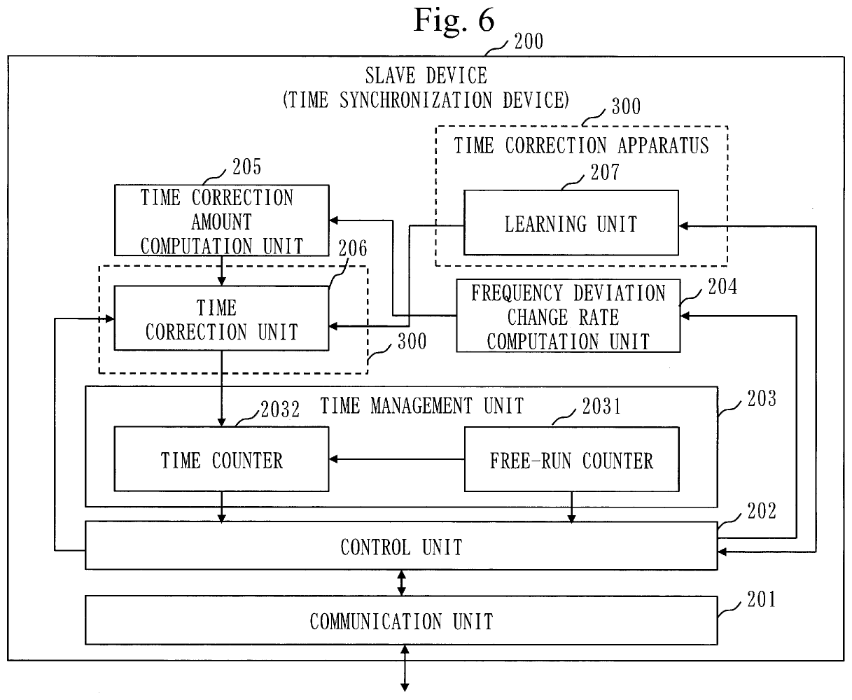

FIG. 6 shows a functional configuration example of the slave device 200 according to the present embodiment.

An exemplary hardware configuration of the slave device 200 according to the present embodiment is as shown in FIG. 2. The functions of a learning unit 207, discussed later, are also implemented by a program and the program for implementing the functions of the learning unit 207 is also executed by the processor 901.

Compared to FIG. 3, the learning unit 207 has been added in FIG. 6. The other elements of FIG. 6 are the same as those shown in FIG. 2. In the present embodiment, the time correction unit 206 and the learning unit 207 correspond to the time correction apparatus 300.

The learning unit 207 is time synchronization AI.

The learning unit 207 learns the temporal transition of the frequency deviation in the learning phase. That is, the learning unit 207 learns the temporal transition of the frequency deviation between the clock frequency of the grand master device 100 and the clock frequency of the slave device 200. Then, the learning unit 207 extracts a pattern of the temporal transition of the frequency deviation as a frequency deviation pattern and computes a frequency deviation change rate in that frequency deviation pattern. The learning unit 207 also performs time integration of the product of the frequency deviation change rate and time and the frequency deviation at a predefined timing to compute a time correction amount for use in time correction on the slave device 200.

When performing the time correction method (2-a), the learning unit 207 learns the periodicity of the pattern of temporal transition of frequency deviation. As mentioned earlier, the pattern of temporal transition of frequency deviation is called the frequency deviation pattern. The learning unit 207 further estimates a start timing of the frequency deviation pattern as the predefined timing. Then, the learning unit 207 performs time integration of the product of the frequency deviation change rate and time and the frequency deviation at the start timing of the frequency deviation pattern to compute a time correction amount.

When performing the time correction method (2-b), the learning unit 207 learns the relationship between the pattern of temporal transition of frequency deviation (the frequency deviation pattern) and control on the slave device 200, and estimates a sign of a sharp change in the frequency deviation. That is, the learning unit 207 extracts a pattern of temporal transition having a sharp change in the frequency deviation change rate as the frequency deviation pattern, and estimates a sign that would occur before the frequency deviation pattern occurs. The learning unit 207 also estimates a detection timing of the sign as the predefined timing, and performs time integration of the product of the frequency deviation change rate and time and the frequency deviation at the detection timing of the sign to compute a time correction amount.

In the present embodiment, the time correction unit 206 performs time correction in the application phase, using the correction amount generated by the learning unit 207.

When performing the time correction method (2-a), the time correction unit 206 performs time correction using the time correction amount generated by the learning unit 207, when the start timing of the frequency deviation pattern has arrived.

When performing the time correction method (2-b), the time correction unit 206 performs time correction using the time correction amount generated by the learning unit 207, when a sign is detected.

If the start timing of the frequency deviation pattern does not arrive in the case of performing the time correction method (2-a), the time correction amount computation unit 205 computes a time correction amount in a similar manner to Embodiment 1.

Likewise, if no sign is detected in the case of performing the time correction method (2-b), the time correction amount computation unit 205 computes a time correction amount in a similar manner to Embodiment 1.

As the other components of FIG. 6 are the same as those shown in FIG. 3, their descriptions are omitted.

First, details of the time correction method (2-a) are described.

**Time Correction Method (2-a)**

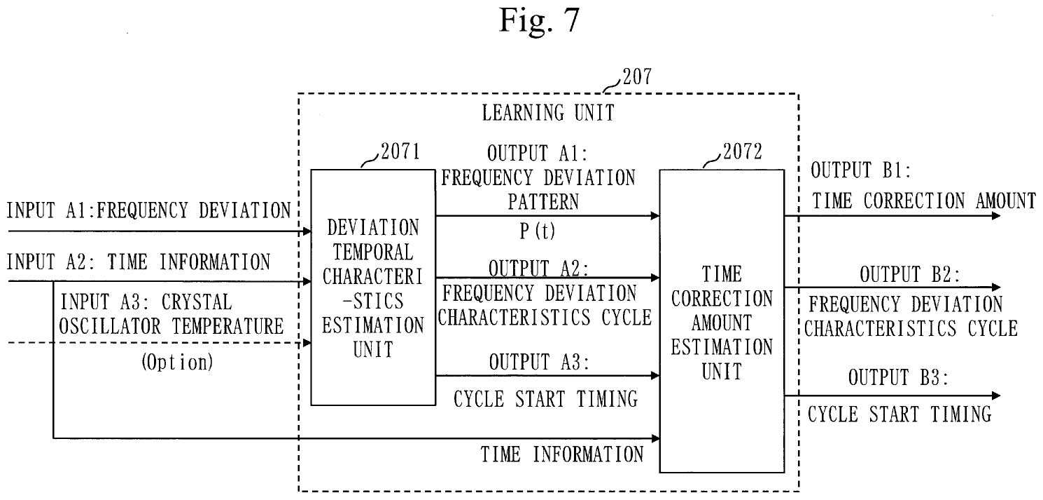

FIG. 7 shows an internal configuration example of the learning unit 207 for implementing the time correction method (2-a).

The learning unit 207 includes a deviation temporal characteristics estimation unit 2071 and a time correction amount estimation unit 2072.

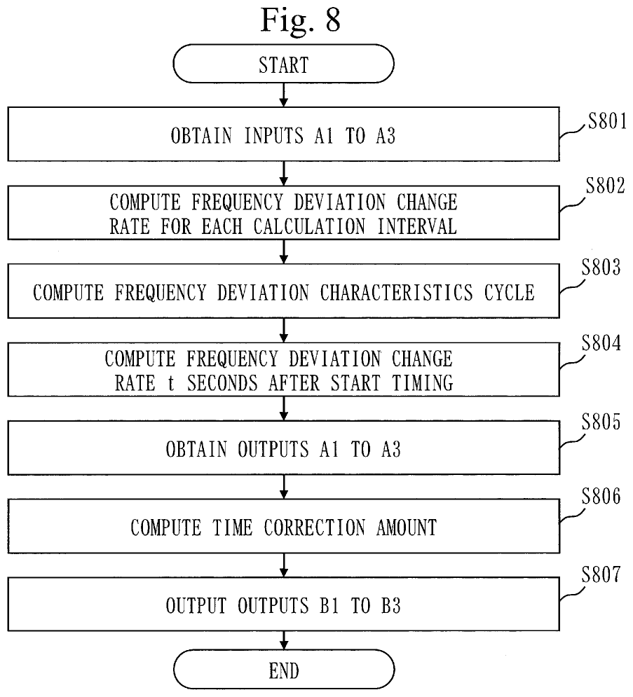

FIG. 8 shows an operation example for the deviation temporal characteristics estimation unit 2071 and the time correction amount estimation unit 2072.

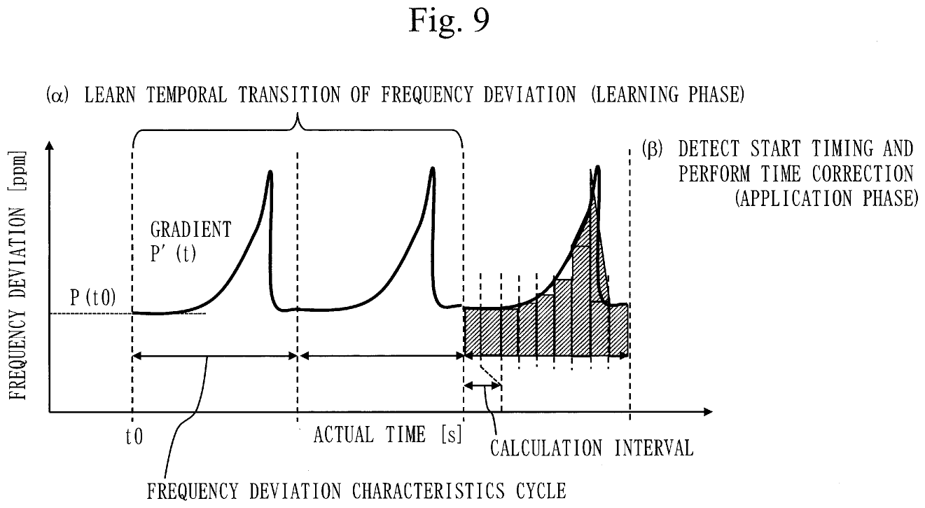

FIG. 9 shows a specific example of the time correction method (2-a).

In the learning phase, the deviation temporal characteristics estimation unit 2071 learns the frequency deviation pattern (output A1), that is, the temporal transition of the frequency deviation, frequency deviation characteristics cycle (output A2), and the start timing of the frequency deviation characteristics cycle (output A3) from the frequency deviation (input A1), time information (input A2), and crystal oscillator temperature (input A3).

The time correction amount estimation unit 2072 also learns the time correction amount (output B1) from the output A1, output A2, and output A3 from the deviation temporal characteristics estimation unit 2071. For learning, a neural network is used. The frequency deviation pattern (output A1) is an expression represented by P(t); details on the way of inputting the frequency deviation pattern (output A1) will be described in Embodiment 3.

(α) Learning Phase

In the following, operations of the deviation temporal characteristics estimation unit 2071 and the time correction amount estimation unit 2072 in the learning phase will be described in accordance with FIG. 8.

First, the deviation temporal characteristics estimation unit 2071 obtains the inputs A1 to A3 described below (step S801):

Input A1: the frequency deviation as measured by IEEE802.1AS or IEEE1588;

Input A2: the time at which the frequency deviation of input A1 was measured; and

Input A3: the temperature of the crystal oscillator (optional).

The input A1 is the frequency deviation in each calculation interval. The calculation interval is a unit time for computing the frequency deviation and the frequency deviation change rate.

The input A3 may be omitted.

Next, the deviation temporal characteristics estimation unit 2071 computes the frequency deviation change rate for each calculation interval (step S802).

More specifically, in calculation interval n, the deviation temporal characteristics estimation unit 2071 computes the change rate (frequency deviation change rate) between the frequency deviation of calculation interval (n−2) and the frequency deviation of calculation interval (n−1). The frequency deviation of calculation interval (n−2) and the frequency deviation of calculation interval (n−1) can be obtained from the input A1.

Next, the deviation temporal characteristics estimation unit 2071 computes a frequency deviation characteristics cycle (step S803).

The deviation temporal characteristics estimation unit 2071 detects that the pattern of temporary transition of the frequency deviation (the waveform pattern of FIG. 9) is periodically repeated, based on the input A1, the input A2, and the frequency deviation change rates for the respective calculation intervals obtained in step S802. The deviation temporal characteristics estimation unit 2071 detects a specific regularity with the temporal transition of the frequency deviation and learns the specific regularity detected. The temporal transition of frequency deviation having this specific regularity is defined as the frequency deviation pattern. Further, the deviation temporal characteristics estimation unit 2071 extracts the cycle of the frequency deviation pattern as the frequency deviation characteristics cycle. At this point, the deviation temporal characteristics estimation unit 2071 also estimates the start timing of the frequency deviation characteristics cycle.

FIG. 9 shows an example of the frequency deviation characteristics cycle.

If the deviation temporal characteristics estimation unit 2071 obtained the input A3 in step S801, the deviation temporal characteristics estimation unit 2071 may compute the frequency deviation characteristics cycle from the temperature change of the crystal oscillator, based on the input A3 (in this case, the method shown in Embodiment 3 is used).

Next, the deviation temporal characteristics estimation unit 2071 computes the frequency deviation change rate P(t) t seconds after the start timing of the frequency deviation characteristics cycle (step S804).

Specifically, the deviation temporal characteristics estimation unit 2071 calculates the frequency deviation P(t) according to expression 14 below. Here, P(t₀) is the frequency deviation at the start timing of the frequency deviation characteristics cycle. P′(t) is the frequency deviation change rate at time t.

P(t)=P′(t)×t+P(t₀) expression 14

The units of P(t₀) and P′(t) are ppm and ppm/s, respectively.

Next, the deviation temporal characteristics estimation unit 2071 outputs the outputs B1 to B3 to the time correction amount estimation unit 2072, and the time correction amount estimation unit 2072 obtains the outputs B1 to B3 (step S805).

Next, the time correction amount estimation unit 2072 computes a time correction amount (ΔC(t)) according to expression 15 based on the result of computation in step S804 from the frequency deviation change rate computed in step S803 (step S806). That is, the time correction amount estimation unit 2072 performs time integration of the product of frequency deviation change rate and time (P′(t)×t) and the frequency deviation (P(t₀)) at the start timing of the frequency deviation pattern to compute the time correction amount (ΔC(t)), according to expression 15.

[FORMULA 14]

ΔC(t)=∫(P′(t)×t+P(t₀))dt[s] expression 15

Finally, the time correction amount estimation unit 2072 outputs the outputs B1 to B3 (step S807).

Specifically, the time correction amount estimation unit 2072 outputs the time correction amount ΔC(t) computed in step S806 to the time correction unit 206 as output B1. The time correction amount estimation unit 2072 also outputs the frequency deviation characteristics cycle (output A2) obtained from the deviation temporal characteristics estimation unit 2071 to the frequency deviation change rate computation unit 204, as output B2. The time correction amount estimation unit 2072 also outputs the start timing of the frequency deviation characteristics cycle (output A3) obtained from the deviation temporal characteristics estimation unit 2071 to the frequency deviation change rate computation unit 204, as output B3.

(β) Application Phase

The frequency deviation change rate computation unit 204 computes the frequency deviation change rate for each calculation interval in accordance with the protocol of IEEE802.1AS or IEEE1588. Then, the frequency deviation change rate computation unit 204 detects the start timing of the frequency deviation characteristics cycle based on the computed frequency deviation change rate and on the frequency deviation characteristics cycle (output B2) and the start timing of the frequency deviation characteristics cycle (output B3) obtained from the time correction amount estimation unit 2072.

Then, after detecting the start timing of the frequency deviation characteristics cycle, the frequency deviation change rate computation unit 204 indicates to the time correction unit 206 that the start timing has arrived.

If it is indicated that the start timing has arrived, the time correction unit 206 performs time correction using the time correction amount (output B1).

If the start timing does not arrive, time correction is performed according to the method of Embodiment 1.

FIG. 9 shows a specific example of the operation of the learning unit 207.

FIG. 9 is described below.

In the learning phase, the deviation temporal characteristics estimation unit 2071 learns the periodicity of the pattern of the temporal transition of the frequency deviation. As a result, the deviation temporal characteristics estimation unit 2071 detects that a waveform pattern is being repeated with the frequency deviation characteristics cycle. Then, the deviation temporal characteristics estimation unit 2071 learns the length of the frequency deviation characteristics cycle and the start timing of the frequency deviation characteristics cycle. The time correction amount estimation unit 2072 computes a time correction amount.

In the application phase, the frequency deviation change rate computation unit 204 detects the start timing of the frequency deviation characteristics cycle. Then, the time correction unit 206 performs time correction using the time correction amount obtained by the learning unit 207.

Details of the time correction method (2-b) are described next.

**Time Correction Method (2-b)**

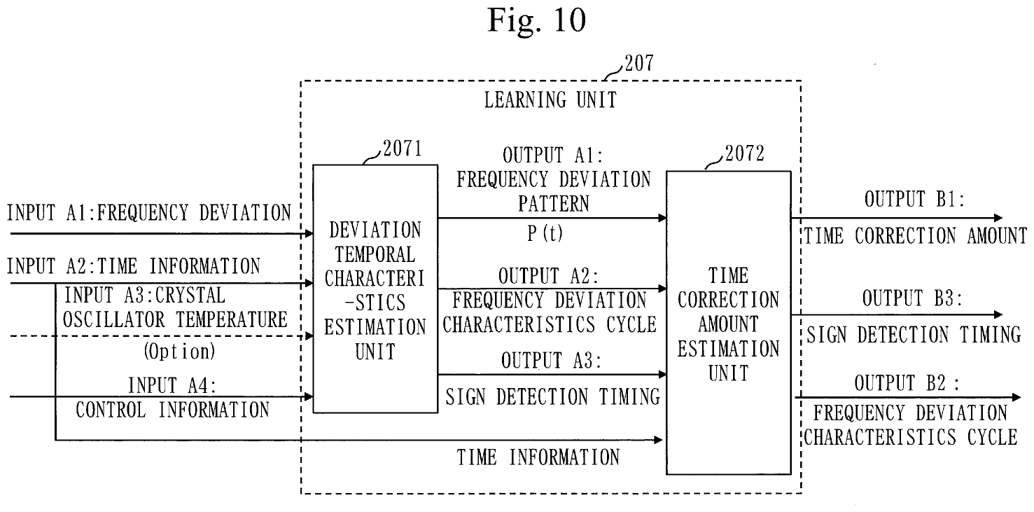

FIG. 10 shows an internal configuration example of the learning unit 207 for implementing the time correction method (2-b).

As with the example of FIG. 7, the learning unit 207 includes the deviation temporal characteristics estimation unit 2071 and the time correction amount estimation unit 2072.

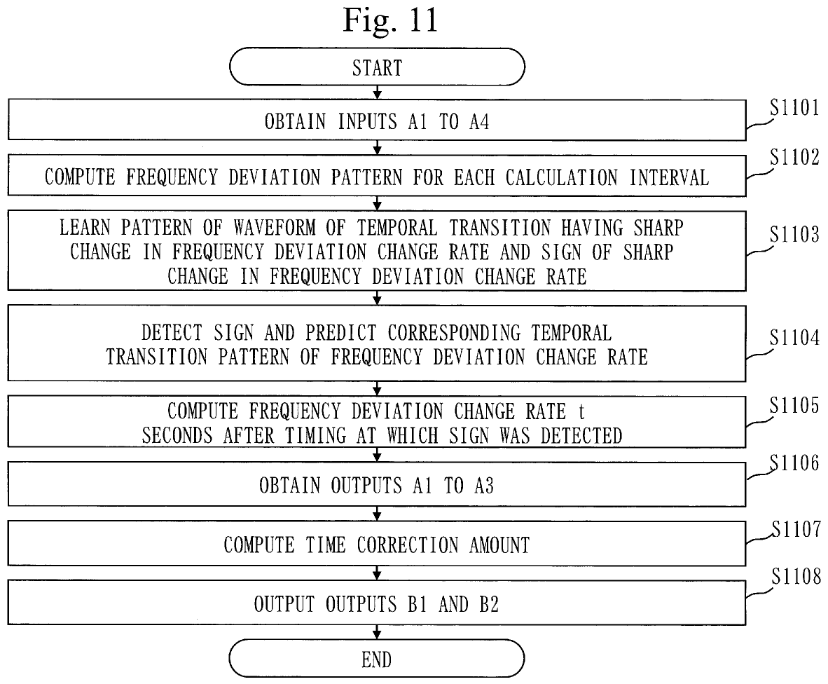

FIG. 11 shows an operation example for the deviation temporal characteristics estimation unit 2071 and the time correction amount estimation unit 2072.

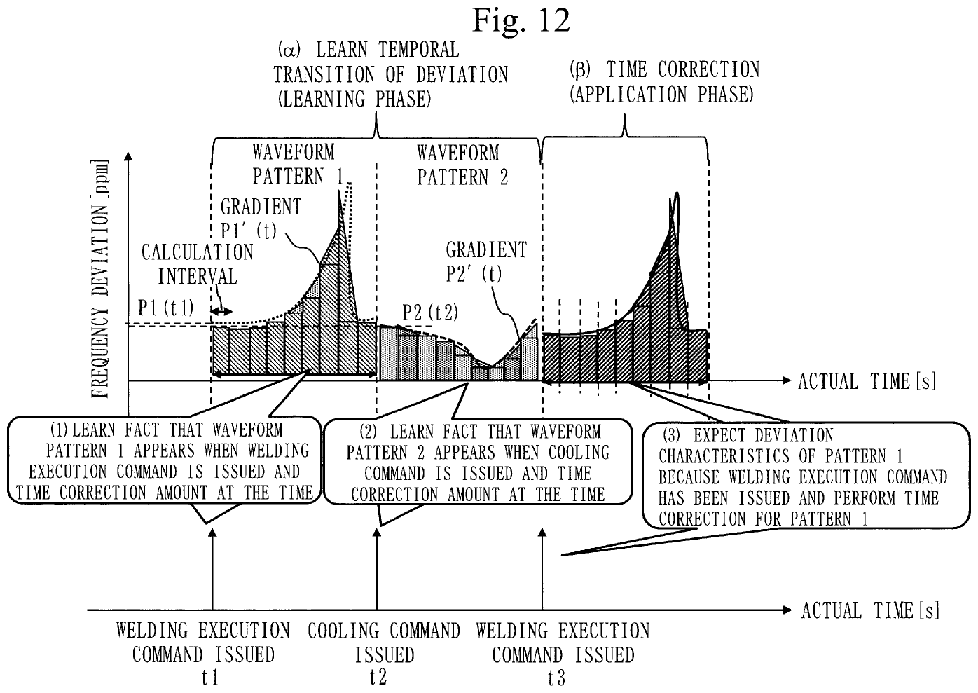

FIG. 12 shows a specific example of the time correction method (2-b).

In the learning phase, the deviation temporal characteristics estimation unit 2071 learns the frequency deviation pattern (output A1), the frequency deviation characteristics cycle (output A2), and the sign detection timing (output A3) from the frequency deviation (input A1), time information (input A2), crystal oscillator temperature (input A3), and control information (input A4).

The time correction amount estimation unit 2072 learns the time correction amount (output B1) from the output A1, output A2, and output A3 from the deviation temporal characteristics estimation unit 2071. For learning, a neural network is used.

(α) Learning Phase

In the following, operations of the deviation temporal characteristics estimation unit 2071 and the time correction amount estimation unit 2072 in the learning phase will be described in accordance with FIG. 11.

First, the deviation temporal characteristics estimation unit 2071 obtains the inputs A1 to A3 described below (step S1101):

Input A1: the frequency deviation as measured by IEEE802.1AS or IEEE1588;

Input A2: the time at which the frequency deviation of input A1 was measured;

Input A3: the temperature of the crystal oscillator (optional); and

Input A4: control information.

The input A1 is the frequency deviation in each calculation interval. The calculation interval is as mentioned previously.

The input A3 may be omitted.

The input A4 is a control command such as turning on/off of a switch. As the input A4, a command to execute welding, electrical discharging, cooling, and the like is input, for example. When welding, electrical discharging, or like is executed on the slave device 200, the temperature of the crystal oscillator in the slave device 200 is expected to sharply rise. By contrast, when cooling is executed on the slave device 200, the temperature of the crystal oscillator in the slave device 200 is expected to sharply drop.

Next, the deviation temporal characteristics estimation unit 2071 computes the frequency deviation pattern for each calculation interval (step S1102). The frequency deviation pattern is a frequency deviation corresponding to a time and is an expression representing the frequency deviation as a function of time. The substance of the frequency deviation pattern will be discussed later.

Next, the deviation temporal characteristics estimation unit 2071 learns the pattern of a waveform of temporal transition having a sharp change in the frequency deviation and a sign of a sharp change in the frequency deviation (step S1103).

The deviation temporal characteristics estimation unit 2071 takes the temporal correlation between the frequency deviation and the control information of input A4, for example, as learning of a sign. Then, the deviation temporal characteristics estimation unit 2071 learns the pattern of the temporal transition of the frequency deviation upon occurrence of a certain event (for example, when a certain command is input).

If the deviation temporal characteristics estimation unit 2071 obtained the input A3 in step S1101, the deviation temporal characteristics estimation unit 2071 may also learn the pattern of the waveform of temporal transition having a sharp change in the frequency deviation and a sign of a sharp change in the frequency deviation from the temperature change of the crystal oscillator (in this case, the method shown in Embodiment 3 is used).

Next, the deviation temporal characteristics estimation unit 2071 detects a sign of a sharp change in the frequency deviation and predicts the corresponding pattern of temporal transition of the frequency deviation (step S1104).

If the deviation temporal characteristics estimation unit 2071 obtained the input A3 in step S1101, the deviation temporal characteristics estimation unit 2071 may detect a sign of a sharp change in the frequency deviation from the temperature change of the crystal oscillator, and predict the corresponding pattern of the temporal transition of the frequency deviation (in this case, the method shown in Embodiment 3 is used).

The pattern of the temporal transition of the frequency deviation predicted by the deviation temporal characteristics estimation unit 2071 corresponds to the frequency deviation pattern.

Next, the deviation temporal characteristics estimation unit 2071 computes the frequency deviation P(t) t seconds after the timing at which the sign was detected, according to expression 16 (step S1105). Here, P(t₀) is the frequency deviation at the timing the sign is detected.

P(t)=P′(t)×t+P(t₀) expression 16

The units of P(t₀) and P′(t) are ppm and ppm/s, respectively.

Next, the deviation temporal characteristics estimation unit 2071 outputs the outputs A1 to A3 to the time correction amount estimation unit 2072, and the time correction amount estimation unit 2072 obtains the outputs A1 to A3 (step S1106).

Next, the time correction amount estimation unit 2072 computes a time correction amount (ΔC(t)) according to expression 17 from the frequency deviation computed in step S1105 (step S1107). That is, the time correction amount estimation unit 2072 performs time integration of the product of the frequency deviation change rate and time (P′(t)×t) and the frequency deviation (P(t₀)) at the detection timing of the sign to compute the time correction amount (ΔC(t)), according to expression 17.

[FORMULA 15]

ΔC(t)=f(P′(t)×t+P(t₀))dt[s] expression 17

Finally, the time correction amount estimation unit 2072 outputs the outputs B1, B2, and B3 (step S1108).

Specifically, the time correction amount estimation unit 2072 outputs the time correction amount ΔC(t) computed in step S1107 to the time correction unit 206, as output B1. The time correction amount estimation unit 2072 also outputs the sign detection timing (output A3) obtained from the deviation temporal characteristics estimation unit 2071 to the time correction unit 206, as output B2.

(β) Application Phase

The deviation temporal characteristics estimation unit 2071 detects a sign of a sharp change in the frequency deviation based on the sign detection timing (output A3).

If the deviation temporal characteristics estimation unit 2071 detects a sign, the deviation temporal characteristics estimation unit 2071 indicates to the time correction unit 206 via the time correction amount estimation unit 2072 that the sign has been detected.

When it is indicated from the deviation temporal characteristics estimation unit 2071 that the sign has been detected, the time correction unit 206 performs time correction using the time correction amount (output B1) obtained from the time correction amount estimation unit 2072.

If no sign is detected, time correction is performed according to the method of Embodiment 1.

FIG. 12 shows a specific example of the operation of the learning unit 207.

FIG. 12 is described below.

In the learning phase, at time t1, input A1, input A2, and input A4 are input to the deviation temporal characteristics estimation unit 2071.

It is assumed that, at time t1, a welding execution command is issued on the slave device 200 as the control information of input A4.

The deviation temporal characteristics estimation unit 2071 learns that the frequency deviation changes with a waveform pattern 1 due to the welding execution command.

The time correction amount estimation unit 2072 calculates a time correction amount ΔC(t1) corresponding to the waveform pattern 1 according to expression 18 below.

The time correction amount estimation unit 2072 outputs the time correction amount ΔC(t1) to the time correction unit 206 as output B1 and outputs the welding execution command to the control unit 202 and the time correction unit 206 as output B2.

[FORMULA 16]

ΔC(t1)=f(P1′(t)x t+P(t1))dt[s] expression 18

In the learning phase, at time t2, input A1, input A2, and input A4 are input to the deviation temporal characteristics estimation unit 2071.

It is assumed that, at time t2, a cooling command is issued on the slave device 200 as the control information of input A4.

The deviation temporal characteristics estimation unit 2071 learns that the frequency deviation changes with a waveform pattern 2 due to the cooling command.

The time correction amount estimation unit 2072 calculates a time correction amount ΔC(t2) corresponding to the waveform pattern 2 according to expression 19 below.

The time correction amount estimation unit 2072 outputs the time correction amount ΔC(t2) to the time correction unit 206 as output B1 and outputs the cooling command to the control unit 202 and the time correction unit 206 as output B2.

[FORMULA 17]

ΔC(t2)=f(P2′(t)x t+P(t2))dt[s] expression 19

In the application phase, at time t3, the control unit 202 indicates the issuance of the welding execution command and the timestamp at that point (time) to the deviation temporal characteristics estimation unit 2071. The deviation temporal characteristics estimation unit 2071 indicates the time of issuance of the welding execution command to the time correction unit 206 via the time correction amount estimation unit 2072.

Since the issuance of a welding execution command is the sign of the waveform pattern 1, the time correction unit 206 performs time correction using the time correction amount ΔC(t1) corresponding to the waveform pattern 1.

A specific way of calculating a time correction amount will be described in Embodiment 3. How the frequency deviation characteristics cycle, the start timing, and the sign detection timing during time correction are utilized will also be described in Embodiment 3.

In the case of varying frequency deviation, the present embodiment also enables time correction in accordance with the varying frequency deviation.

Additionally, since time correction in the present embodiment is performed using a time correction amount resulting from learning, it does not require computation of frequency deviation change rate and time correction amount, allowing reduced computational burden.

### Embodiment 3

The present embodiment also describes an example where the temporal transition of the frequency deviation change rate is learned by means of AI and time correction is performed based on the result of learning.

In the present embodiment, mainly differences from Embodiment 1 and Embodiment 2 are discussed.

Matters that are not described below are similar to Embodiment 1 and Embodiment 2.

In the present embodiment, an exemplary configuration of the time synchronization system 1000 is also as shown in FIG. 1.

In the present embodiment, an exemplary hardware configuration of the slave device 200 is also as shown in FIG. 2. In the present embodiment, an exemplary functional configuration of the slave device 200 is also as shown in FIG. 6.

Embodiment 3 is different from Embodiment 2 in the way of computing the frequency deviation. In Embodiment 2, a frequency deviation measured by a time synchronization protocol is used as it is. In Embodiment 3, the correlation between the temperature of the crystal oscillator and a frequency deviation measured by a protocol is estimated by AI. In Embodiment 3, AI also determines frequency deviation temperature characteristics specific to the crystal oscillator. In Embodiment 3, AI computes a frequency deviation for a crystal oscillator temperature input to the AI, from the determined frequency deviation temperature characteristics and performs time correction with using the frequency deviation. As the present embodiment enables analysis of not only frequency deviation measured by a protocol but also the temperature characteristics of frequency deviation inherent in the crystal oscillator, it is possible to calculate a time correction amount that is closer to the actual frequency deviation of the crystal oscillator.

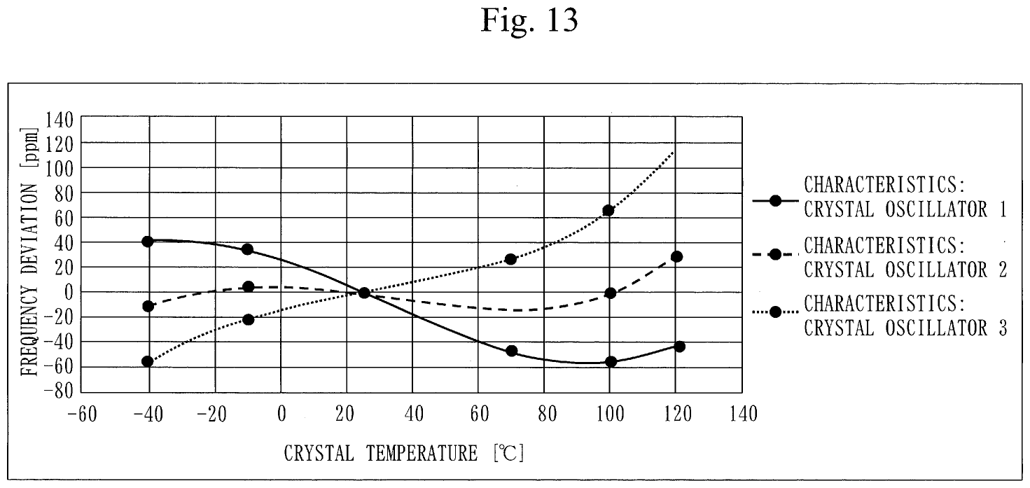

Crystal oscillators have different frequency deviations from one individual crystal oscillator to another as in FIG. 13, and the frequency deviation changes with the temperature of crystal. Such characteristics of frequency deviation different from individual to individual are learned by AI. Furthermore, the AI estimates a time correction amount on the basis of information on the frequency deviation characteristics learned. The substance of this AI is the learning unit 207. The learning unit 207 according to Embodiment 3 is internally composed of a deviation temperature characteristics estimation unit 2075, a deviation temporal characteristics estimation unit 2076, and a time correction amount estimation unit 2077, as shown in (1) to (3) below.

(1) Deviation Temperature Characteristics Estimation Unit 2075

The deviation temperature characteristics estimation unit 2075 learns the frequency deviation temperature characteristics of the crystal oscillator in the slave device 200 and estimates the frequency deviation temperature characteristics.

(2) Deviation Temporal Characteristics Estimation Unit 2076

The deviation temporal characteristics estimation unit 2076 computes a frequency deviation with respect to the temperature from the frequency deviation temperature characteristics estimated by the deviation temperature characteristics estimation unit 2075 and learns the temporal transition of the frequency deviation. The deviation temporal characteristics estimation unit 2076 computes a frequency deviation change rate and a frequency deviation pattern (the temporal transition of frequency deviation with a specific regularity) from the temporal transition of frequency deviation, and outputs the frequency deviation change rate and the frequency deviation pattern to the time correction amount estimation unit 2077 which is discussed later. The deviation temporal characteristics estimation unit 2076 learns the frequency deviation characteristics cycle, the start timing of the frequency deviation pattern, the frequency deviation pattern, and the sign detection timing as in Embodiment 2.

(3) Time Correction Amount Estimation Unit 2077

The time correction amount estimation unit 2077 learns the time correction amount for the slave device 200 on the basis of the temporal transition of the frequency deviation learned by the deviation temporal characteristics estimation unit 2076, and estimates a time correction amount.

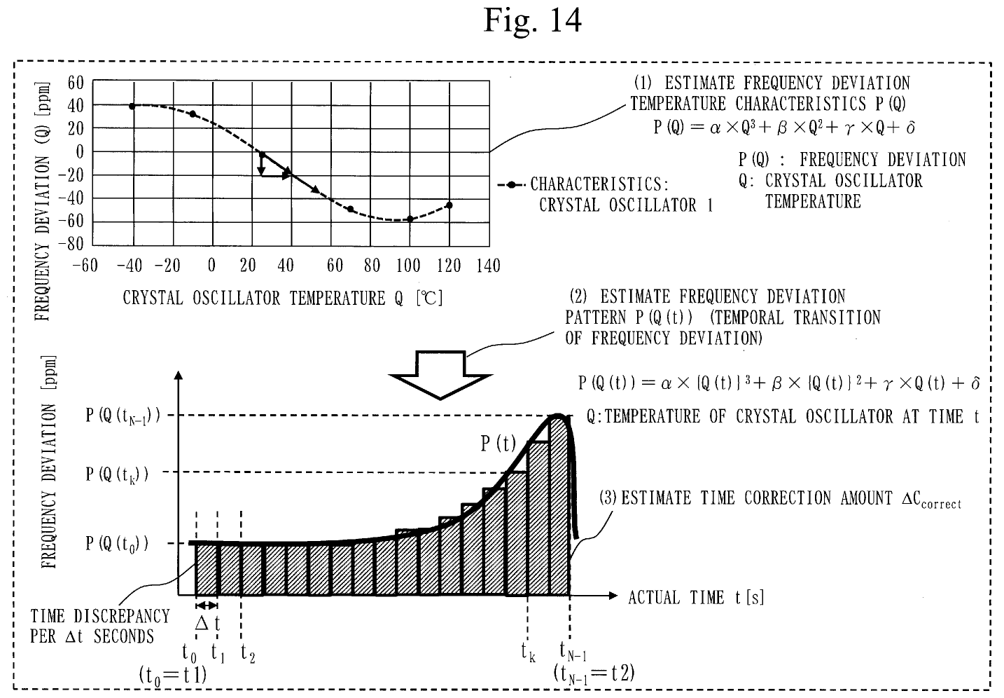

The relationship among the deviation temperature characteristics estimation unit 2075, the deviation temporal characteristics estimation unit 2076, and the time correction amount estimation unit 2077 is shown in FIG. 14.

FIG. 14 represents that the relationship between frequency deviation and temperature can be converted into the relationship between frequency deviation and a time using expressions of the frequency deviation temperature characteristics P(Q) and frequency deviation pattern P(Q(t)), with which a time correction amount can be then estimated.

In the learning unit 207, the deviation temperature characteristics estimation unit 2075 learns the frequency deviation temperature characteristics P(Q) in accordance with (1) of FIG. 14. Then, as shown in (2) of FIG. 14, the deviation temporal characteristics estimation unit 2076 estimates a frequency deviation pattern P(Q(t)) from the frequency deviation temperature characteristics P(Q) learned by the deviation temperature characteristics estimation unit 2075 and time information which is input. Then, as shown in (3) of FIG. 14, the time correction amount estimation unit 2077 estimates the time correction amount ΔC_{correct} corresponding to the frequency deviation pattern P(Q(t)). That is, the time correction amount estimation unit 2077 calculates the frequency deviation and frequency deviation change rate for each frequency deviation pattern P(Q(t)), and from the time integration of them, estimates the time correction amount ΔC_{correct}.

The time correction amount ΔC_{correct} corresponds to the area of the hatched portion of FIG. 14.

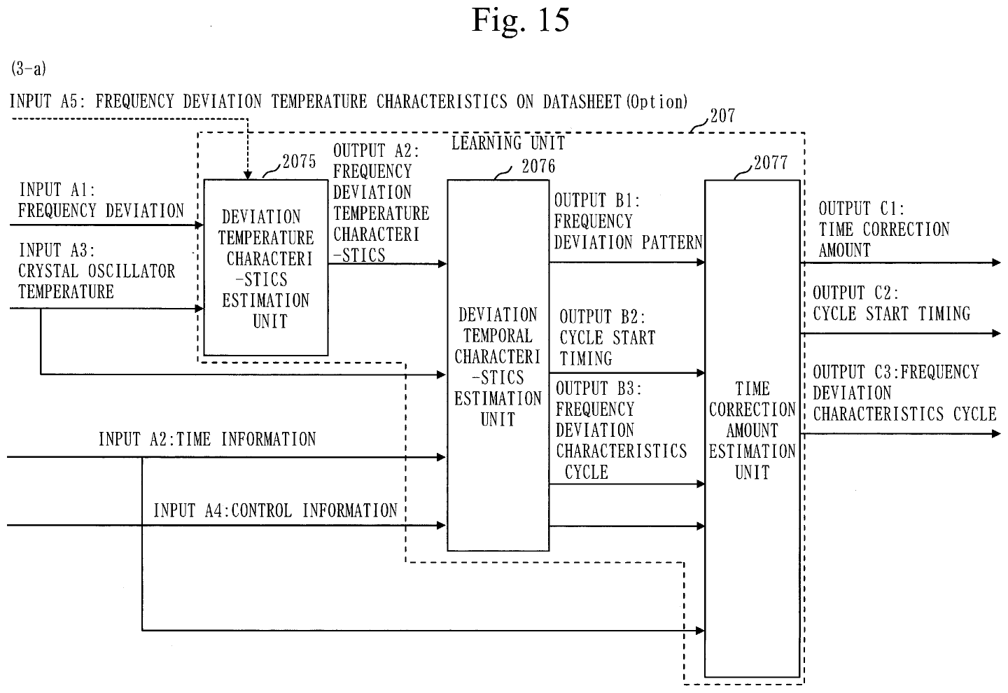

Functional blocks for estimating the time correction amount by means of the AI are shown in FIG. 15.

In the present embodiment, the following operations are performed in (α) learning phase and (β) application phase.

(α) Learning Phase

In the learning phase, supervised learning (a neural network) is carried out. The temperature of the crystal oscillator and the frequency deviation are input to the deviation temperature characteristics estimation unit 2075, and the deviation temperature characteristics estimation unit 2075 creates a model of the frequency deviation temperature characteristics.

(1) The deviation temperature characteristics estimation unit 2075 obtains input A1: the frequency deviation measured by a time synchronization protocol and input A3: the crystal oscillator temperature obtained from a sensor. The deviation temperature characteristics estimation unit 2075 may also obtain input A5: frequency deviation temperature characteristics on a datasheet.

(2) The deviation temperature characteristics estimation unit 2075 approximates the characteristics of the frequency deviation with respect to the temperature as a cubic function on the basis of the crystal oscillator temperature and frequency deviation obtained, and learns the values of coefficients (α, β, γ, and δ in expression 20) for representing the frequency deviation temperature characteristics. Then, the deviation temperature characteristics estimation unit 2075 outputs the frequency deviation temperature characteristics (output A2) in which the learned coefficient values (α, β, γ, and δ) are included to the deviation temporal characteristics estimation unit 2076. The frequency deviation temperature characteristics (output A2) is a function with the temperature being a variable and can be represented by the expression below:

P(Q)=αQ³+βQ²+γQ+δ [ppm] expression 20

P(Q): frequency deviation [ppm] (input A1)

Q: the temperature of the crystal oscillator [° C.] (input A3)

If the deviation temperature characteristics estimation unit 2075 has obtained the frequency deviation temperature characteristics on the datasheet (input A5), the deviation temperature characteristics estimation unit 2075 learns the value of coefficients (α, β, γ, and δ) exhibiting characteristics closest to the characteristics on the datasheet on the basis of the frequency deviation temperature characteristics and the frequency deviation obtained. Then, the deviation temperature characteristics estimation unit 2075 outputs the frequency deviation temperature characteristics (output A2) in which the learned coefficient values (α, β, γ, and δ) are included to the deviation temporal characteristics estimation unit 2076.

In learning of the coefficient values (α, β, γ, and δ) of the frequency deviation temperature characteristics, the deviation temperature characteristics estimation unit 2075 substitutes the frequency deviation measured by the protocol (input A1) into P(Q) on the left side of expression 20 and substitutes the temperature of the crystal oscillator at the time of measurement of the frequency deviation (input A3) into Q on the right side of expression 20. By repeatedly taking measurements by the protocol, the deviation temperature characteristics estimation unit 2075 solves simultaneous equations with four variables for the four coefficients, α, β, γ, and δ, and derives the values of the coefficients.

(3) The deviation temporal characteristics estimation unit 2076 obtains the frequency deviation temperature characteristics (output A2) computed in (2) above and the crystal oscillator temperature (input A3). Then, the deviation temporal characteristics estimation unit 2076 computes the frequency deviation and the frequency change rate using the frequency deviation temperature characteristics (output A2) and the crystal oscillator temperature (input A3). Further, the deviation temporal characteristics estimation unit 2076 obtains the time at which the crystal oscillator temperature was input (input A2: time information). The deviation temporal characteristics estimation unit 2076 also measures the temporal transition of the frequency deviation and outputs the temporal transition of the frequency deviation to the time correction amount estimation unit 2077 as the frequency deviation pattern (output B1). The deviation temporal characteristics estimation unit 2076 also detects the temporal transition of frequency deviation having a specific regularity as the frequency deviation pattern. Further, the deviation temporal characteristics estimation unit 2076 detects a sign that occurs before the frequency deviation pattern occurs and stores the sign. The frequency deviation pattern and the sign are as shown in either (3-a) or (3-b) below.

(3-a) (FIG. 15)

As with (2-a) in Embodiment 2, the deviation temporal characteristics estimation unit 2076 detects that the frequency deviation pattern (waveform pattern) is being repeated at the frequency deviation characteristics cycle and learns the frequency deviation characteristics cycle and the start timing of the frequency deviation characteristics cycle. The deviation temporal characteristics estimation unit 2076 outputs the frequency deviation characteristics cycle (output B3) and the cycle start timing (output B2) to the time correction amount estimation unit 2077. The cycle start timing (output B2) is the start timing of the frequency deviation characteristics cycle. The time correction amount estimation unit 2077 learns the time correction amount corresponding to the frequency deviation characteristics pattern, as with (2-a) in Embodiment 2.

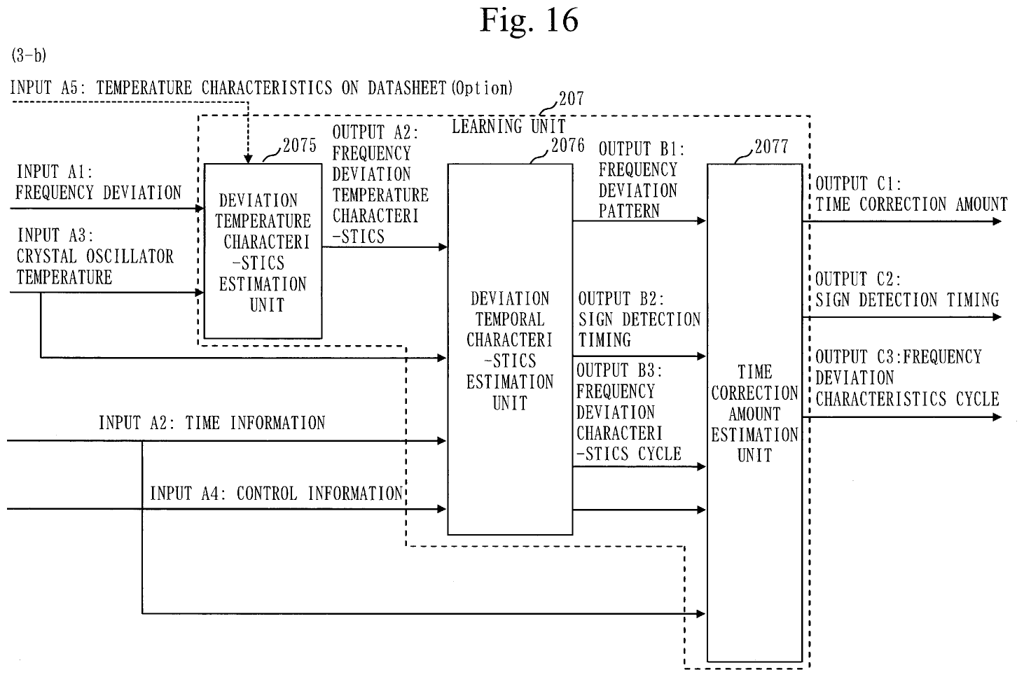

(3-b) (FIG. 16)

As with (2-b) in Embodiment 2, the deviation temporal characteristics estimation unit 2076 obtains control information (input A4). The deviation temporal characteristics estimation unit 2076 also learns the temporal transition of the frequency deviation with respect to the control information as the frequency deviation pattern. The deviation temporal characteristics estimation unit 2076 also learns the length of the wavelength of the temporal transition as the frequency deviation characteristics cycle and learns the sign detection timing. The sign detection timing is the timing of occurrence of a sign that occurs before the frequency deviation pattern occurs. The deviation temporal characteristics estimation unit 2076 outputs the sign detection timing (output B2) and the frequency deviation characteristics cycle (output B3) to the time correction amount estimation unit 2077.

The concept of how to calculate the time correction amount of (3-a) and (3-b) is similar to Embodiment 2, but the present embodiment is different in that the temporal transition of the frequency deviation is determined from information on the crystal oscillator temperature and time information.

The substance of the frequency deviation pattern is now described. The substance of the frequency deviation pattern is an expression of frequency deviation P(t) with time t being a variable. The deviation temporal characteristics estimation unit 2076 sets a format of a function for representing P(t) and an identification number of identifying the format.

The deviation temporal characteristics estimation unit 2076 outputs coefficient values of a polynomial of P(t), degrees of t of the respective terms, and the identification number of the function format to the time correction amount estimation unit 2077. In FIGS. 15 and 16, this information is denoted as output B1: frequency deviation pattern.

For example, when P(t) can be represented by a third order polynomial like P(t)=At³+Bt²+Ct+D, the deviation temporal characteristics estimation unit 2076 outputs an identifier (identification number) representing that the function format is a third order polynomial, the respective values of coefficients A, B, C and D, and the respective degrees of t terms in the above expression to the time correction amount estimation unit 2077. When P(t) can be represented by an exponential function like P(t)=A×exp(t)+B, the deviation temporal characteristics estimation unit 2076 outputs an identifier (identification number) representing that the function format is an exponential function, the respective values of coefficients A and B, and the respective degrees of t terms in the above expression to the time correction amount estimation unit 2077.

As the specific assignments of function format and the identification number depend on the implementation method, their details are not defined herein.

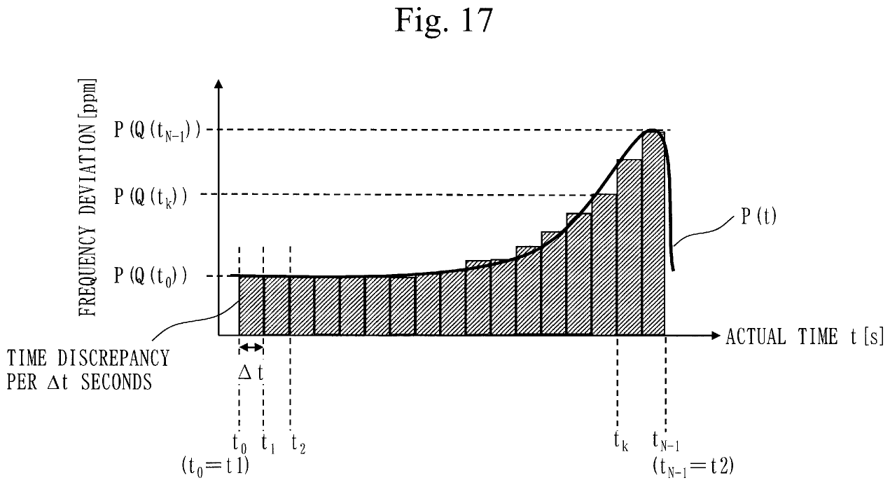

The concept of calculation of time correction amount is illustrated in FIG. 17.

As described in FIG. 17, from expression 21, the frequency deviation for the crystal oscillator temperature Q(t) at time t can be represented by the expression below:

P(Q(t))=α×{Q(t)}³+β×{Q(t)}²+γ×Q(t)+δ expression 21

Given t₀=t1 and t_{N-1}=t2, a time discrepancy due to frequency deviation from t1 to t2 can be represented as the sum of frequency deviation P(Q(t)) from sections t1 to t2×a small time Δt. That is, a time correction amount for canceling out the time discrepancy is calculated as:

[FORMULA 18]

$$Δ {C}_{c o r r e c t} = P ( Q ( {t}_{0} ) ) ⨯ Δ t + P ( Q ( {t}_{1} ) ) ⨯ Δ t + … + P ( Q ( {t}_{N - 1} ) ) ⨯ Δ t = {\sum }_{k = 0}^{N} P ( {t}_{k} ) ⨯ Δ t \qquad expression 22$$

Since Δt is a small time, the expression can be transformed into the expression below. Thus, the time correction amount is computed by the expression below:

[FORMULA 19]

$${Δ C}_{c o r r e c t} = {lim}_{t \to 0} {\sum }_{k = 0}^{N - 1} P ( {t}_{k} ) ⨯ Δ t = {\int }_{t 1}^{t 2} P ( Q ( t ) ) dt \qquad expression 23$$

(β) Application Phase

The deviation temporal characteristics estimation unit 2076 obtains the crystal oscillator temperature (input A3), time information (input A2), and control information (input A4). The deviation temporal characteristics estimation unit 2076 also detects the frequency deviation characteristics cycle and the start timing of the frequency deviation characteristics cycle, which were learned in the learning phase (3-a), and outputs the frequency deviation characteristics cycle and the start timing of the frequency deviation characteristics cycle to the time correction amount estimation unit 2077. The time correction amount estimation unit 2077 outputs the time correction amount corresponding to the frequency deviation characteristics cycle to the time correction unit 206.

The time correction amount can be derived by time integration of the frequency deviation pattern P(Q(t)), as in expression 23.

The time correction unit 206 performs time correction using the time correction amount.

Alternatively, the deviation temporal characteristics estimation unit 2076 detects the sign detection timing and the frequency deviation pattern from the temporal transition of the frequency deviation for the control information learned in the learning phase (3-b), and outputs the sign detection timing and the frequency deviation pattern to the time correction amount estimation unit 2077. The time correction amount estimation unit 2077 outputs the time correction amount corresponding to the frequency deviation pattern to the time correction unit 206. The time correction unit 206 performs time correction using the time correction amount.

The frequency deviation characteristics cycle, the start timing of the frequency deviation characteristics cycle, the sign detection timing, and the frequency deviation pattern described above are determined by substituting information on the crystal oscillator temperature into expression 20 and converting the crystal oscillator temperature to a value of frequency deviation. As an alternative, the frequency deviation characteristics cycle and the like may be directly determined from the temporal transition of the crystal oscillator temperature before conversion to frequency deviation. This is because, since the crystal oscillator temperature and the time corresponding to it have been determined in the course of determining the temporal transition of frequency deviation, the regularity of the temporal transition of temperature can also be learned by A1 and used as a pattern for sign detection as with the frequency deviation pattern mentioned above.

Time Correction

The method of time correction is described.

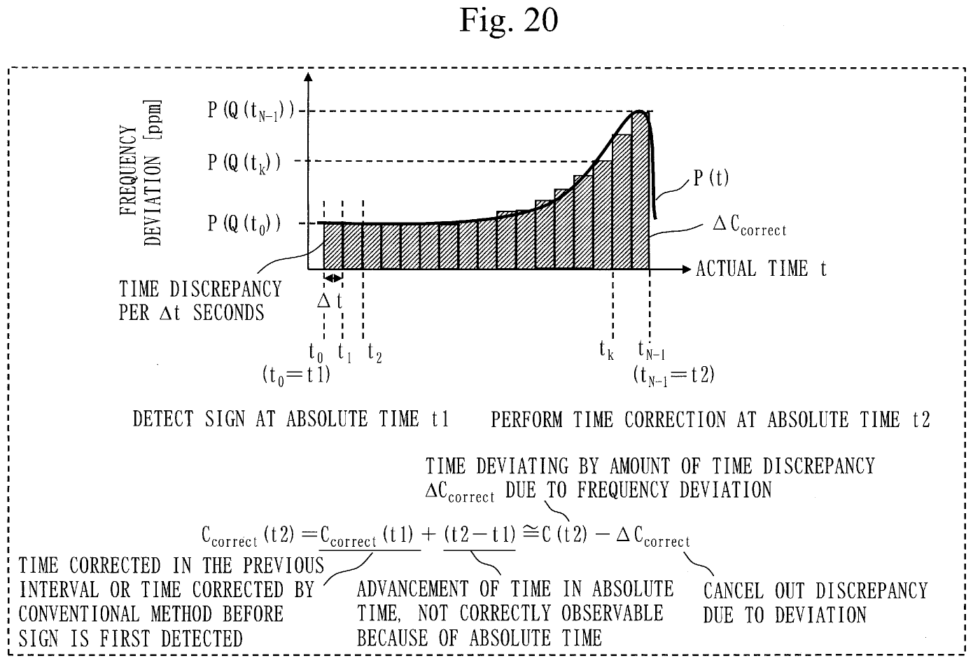

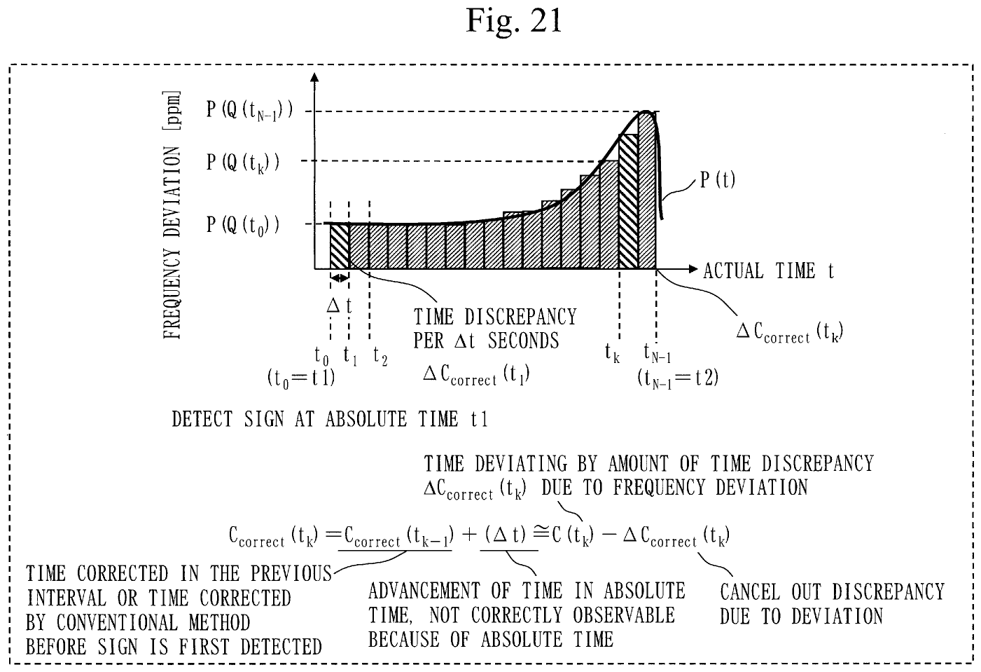

In the cases of (3-a) and (3-b), the time correction amount estimation unit 2077 similarly calculates a time correction amount as in FIGS. 20 and 21.

In FIG. 20, assume a case where the deviation temporal characteristics estimation unit 2076 detects a sign at absolute time t1 and the time correction unit 206 performs time correction at absolute time t2. The time correction amount estimation unit 2077 estimates the time counter value at absolute time t2, treating absolute time t1 as a starting point. The time counter value corresponding to absolute time t1 is equivalent to the start timing of the frequency deviation characteristics cycle in (3-a) or the sign detection timing in (3-b).

The time counter value at absolute time t1 is denoted as C(t1). The time counter value (time-corrected) at absolute time t1 is denoted as C_{correct}(t1). The time counter value before correction at absolute time t2 is denoted as C(t2). The time counter value after correction at absolute time t2 is denoted as C_{correct}(t2). In this case, the time counter will be corrected in the following manner. From the time correction amount estimation unit 2077, the time correction amount is input to the time correction unit 206, and the time correction unit 206 performs time correction for the slave device 200.

Because the amount of time discrepancy from absolute time t1 to absolute time t2 is reflected in C(t2), the time correction unit 206 is able to perform time correction by subtracting the time correction amount ΔC_{correct} from the time counter value C(t2), as shown in expression 24.

[FORMULA 20]

$${C}_{c o r r e c t} ( t 2 ) = {C}_{c o r r e c t} ( t 1 ) + ( t 2 - t 1 ) ≅ C ( t 2 ) - Δ {C}_{correct} \qquad expression 24$$

Here, expression 24 is described.

As noted earlier, C_{correct}(t2) represents the time counter value of the slave device 200 at absolute time t2 after time correction. C_{correct}(t1) represents the time counter value of the slave device 200 at absolute time t1 after time correction.

(t2−t1) is the time elapsed from t1 to t2 in absolute time. Meanwhile, for the time on the slave device 200, an error from the absolute time equivalent to the frequency deviation occurs due to frequency deviation. This error corresponds to the hatched portion of the graph in FIG. 20. Accordingly, at absolute time t2, correction to an accurate time is possible by subtracting the time correction amount ΔC_{correct} estimated by the time correction amount estimation unit 2077 from the time counter value C(t2) of the slave device 200, which is experiencing an error of frequency deviation.

Since at the point of absolute time t1, the time has been corrected in the previous interval, the already corrected time at absolute time t1 is denoted as C_{correct}(t1). Also in a case where a sign has been detected first, the corrected time at absolute time t1 is denoted as C_{correct}(t1) since the time has been already corrected by the conventional method by the time when the sign was detected.

The time correction unit 206 may also perform time correction for each small section of Δt, instead of performing time correction collectively at the timing of absolute time t2 for the section from absolute time t1 to absolute time t2 (the frequency deviation characteristics cycle) as in FIG. 21.

In this case again, after the deviation temporal characteristics estimation unit 2076 detected a sign, the time correction unit 206 performs time correction for each small section of Δt in accordance with an estimated frequency deviation characteristics cycle. For example, given that the temporal transition of frequency deviation shown in FIG. 21 is being repeated, the time correction unit 206 performs time correction for the small section Δt from time t₀ to time t₁. Subsequently, the time correction unit 206 performs time correction at each small section Δt. Then, after performing time correction for the small section Δt from time t_{N-2} to time t_{N-1}, the time correction unit 206 further performs time correction with the time correction amount for the small section Δt from time t₀ to t₁ in the subsequent frequency deviation characteristics cycle. Subsequently, the time correction unit 206 will repeat this operation in each frequency deviation characteristics cycle.

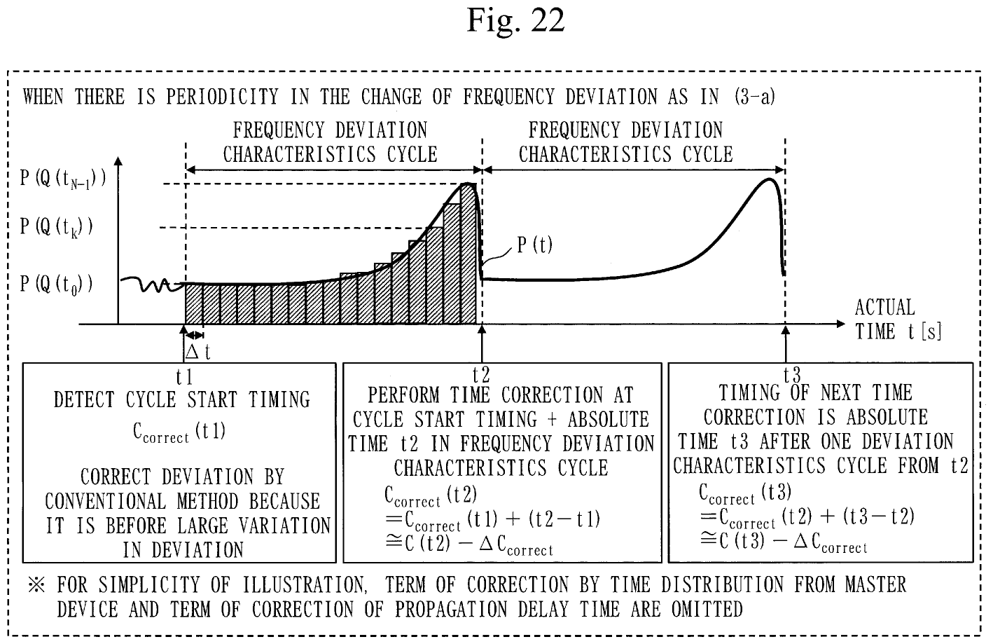

FIG. 22 shows an example of time correction in a case where the temporal transition of frequency deviation has periodicity, as in (3-a).

Also in FIG. 22, C_{correct}(t2) represents the time counter value of the slave device 200 at absolute time t2 after time correction, as in FIG. 20. C_{correct}(t1) represents the time counter value of the slave device 200 at absolute time t1 after time correction. (t2−t1) is the time elapsed from t1 to t2 in absolute time. Meanwhile, for the time on the slave device 200, an error from the absolute time equivalent to the frequency deviation occurs due to frequency deviation. This error corresponds to the hatched portion of the graph in FIG. 22. Accordingly, at absolute time t2, the time correction unit 206 can correct the time to an accurate time by subtracting the time correction amount ΔC_{correct} estimated by the time correction amount estimation unit 2077 from the time counter value C(t2) of the slave device 200, which is experiencing an error of frequency deviation. Since the frequency deviation pattern is the same at the frequency deviation characteristics cycle (the length of the cycle (t2−t1)), the time correction unit 206 performs time correction by subtracting the time correction amount ΔC_{correct} from the time counter value C(t3) also at absolute time t3. As a result, the time counter value of the slave device 200 is corrected to C_{correct}(t3).

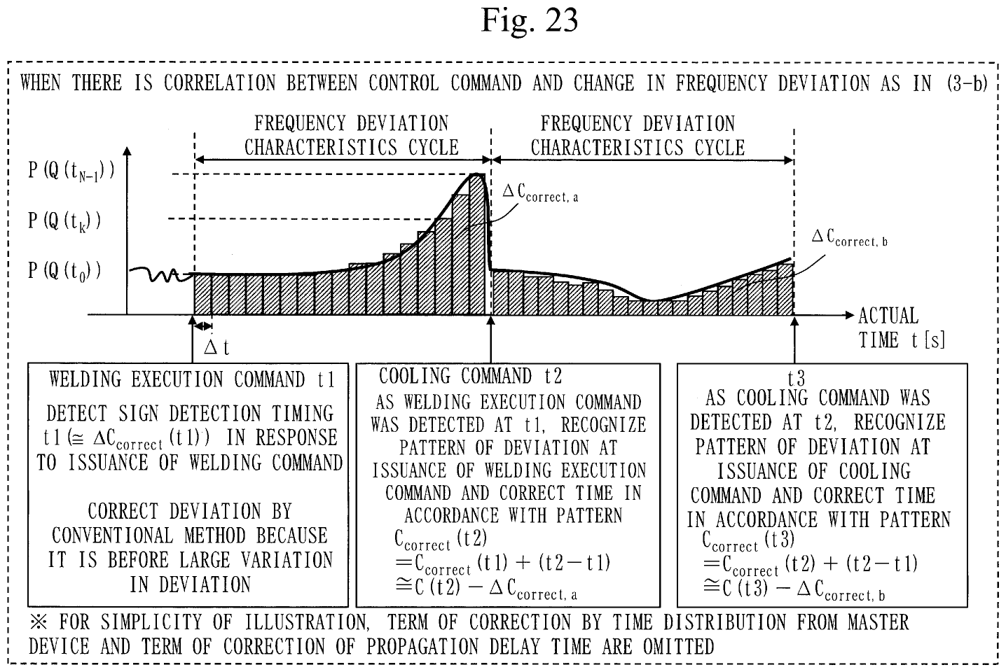

FIG. 23 shows an example of time correction in a case where there is correlation between a control command and change in frequency deviation, as in (3-b).

Also in FIG. 23, C_{correct}(t2) represents the time counter value of the slave device 200 at absolute time t2 after time correction, as in FIG. 20. C_{correct}(t1) represents the time counter value of the slave device 200 at absolute time t1 after time correction. (t2−t1) is the time elapsed from t1 to t2 in absolute time. Meanwhile, for the time on the slave device 200, an error from the absolute time equivalent to the frequency deviation occurs due to frequency deviation. This error corresponds to the hatched portion of the graph in FIG. 23. Accordingly, at absolute time t2, the time correction unit 206 can correct the time to an accurate time by subtracting the time correction amount ΔC_{correct,a} estimated by the time correction amount estimation unit 2077 from the time counter value C(t2) of the slave device 200, which is experiencing an error of frequency deviation. The time correction amount ΔC_{correct,a} represents the amount of time discrepancy due to frequency deviation from when a welding execution command is issued to when the duration of the frequency deviation characteristics cycle has elapsed. Thus, the time correction unit 206 can correct the time by subtracting the value of the time correction amount ΔC_{correct,a} from the time counter value of the slave device 200 at a point of time when the duration of the frequency deviation characteristics cycle has passed from the time when the welding execution command was issued. Similarly, time correction amount ΔC_{correct,b} represents the amount of time discrepancy due to frequency deviation from when a cooling command is issued to when the duration of the frequency deviation characteristics cycle has elapsed. As with the welding execution command, the time correction unit 206 can correct the time by subtracting the value of the time correction amount ΔC_{correct,b} from the time counter value of the slave device 200 at a point of time when the duration of the frequency deviation characteristics cycle has passed from the time when the cooling command was issued.

### Specific Examples

Specific examples are shown below.

****Learning Phase****

(1) The deviation temperature characteristics estimation unit 2075 obtains the crystal oscillator temperature (input A3) from a sensor and further obtains the frequency deviation (input A1) measured by the protocol. The deviation temperature characteristics estimation unit 2075 keeps the time information of the time when it obtained the crystal oscillator temperature (input A3) from the sensor. Timestamps for such time information are obtained by the time management unit 203. For the frequency deviation pattern, there are the case of (3-a) where the same pattern is observed periodically, discussed later, and the case of (3-b) where a specific frequency deviation pattern appears in response to a certain control command, discussed later. In the case of (3-a), the learning unit 207 performs learning with the configuration of FIG. 15, while in the case of (3-b), the learning unit 207 performs learning with the configuration of FIG. 16.

(2) The deviation characteristics estimation unit 2075 estimates the frequency deviation temperature characteristics of the crystal oscillator in the slave device 200, like FIG. 14 (crystal oscillator 1), from information on the crystal oscillator temperature and frequency deviation obtained in (1).

The frequency deviation temperature characteristics is an expression that approximates the frequency deviation with a cubic function using temperature as a variable. The deviation temporal characteristics estimation unit 2076 computes the coefficients of the respective terms of the cubic function and inputs the coefficient values to the time correction amount estimation unit 2077. Estimation of the frequency deviation temperature characteristics is carried out in the learning phase. For example, suppose P(Q) is the frequency deviation with respect to temperature, the frequency deviation characteristics can be represented by the expression below:

P(Q)=αQ³+βQ²+γQ+δ [ppm] expression 20

The deviation temporal characteristics estimation unit 2076 obtains the frequency deviation and the crystal oscillator temperature at the time, substitutes the frequency deviation and the crystal oscillator temperature at the time into expression 20 above, and solves simultaneous equations with four variables, for coefficients α, β, γ, and δ. Determining the solution requires information on the frequency deviation and the crystal oscillator temperature for four measuring points at minimum. The more the measuring points, more likely coefficients will be derived by the deviation temporal characteristics estimation unit 2076. For example, the deviation temporal characteristics estimation unit 2076 may output an average of each coefficient over the number of measurements as a final coefficient. Alternatively, the deviation temporal characteristics estimation unit 2076 may derive a coefficient closest to the characteristics in an input datasheet from measurement results in advance. When characteristics in a datasheet are used, an expression in the format of expression 20 would be input to the deviation temporal characteristics estimation unit 2076.

In the foregoing manner, the deviation temporal characteristics estimation unit 2076 estimates the coefficient values of α, β, γ, and δ in the expression above and inputs the characteristics (a formula) to the time correction amount estimation unit 2077.

(3) The time correction amount estimation unit 2077 estimates a time correction amount corresponding to the frequency deviation pattern, from the frequency deviation pattern input from the deviation temporal characteristics estimation unit 2076 and time information corresponding to the time at which that deviation was obtained (the time when the crystal oscillator temperature was obtained). The way of calculating a time correction amount is based on a similar concept to Embodiment 2. That is, the time correction amount estimation unit 2077 determines the time-integrated value of the product of the frequency deviation change rate and time and the frequency deviation at a predefined timing, as the time correction amount. However, as the frequency deviation in Embodiment 3 is represented by a function of temperature and time, the temperature frequency deviation is represented as P(Q(t)).

Q(t) represents the temperature of the crystal oscillator at time t. The temperature frequency deviation at time t is represented as P(Q(t)). Then, the time correction amount ΔC(t) in the section from time t1 to time t2 is represented by the expression below. The process of deriving the expression below is as described in FIG. 17.

[FORMULA 21]

$$Δ C ( t ) = {\int }_{t 1}^{t 2} P ( Q ( t ) ) d t = {\int }_{t 1}^{t 2} \{ P ( Q ( t 1 ) ) + {P}^{′} ( Q ( t ) ) ⨯ t \} dt \qquad expression 25$$

P(Q(t)) is a substitution of function Q(t) representing the temperature at time t into the temperature Q of expression 20, where P(Q(t)) is represented by the expression 21 shown earlier.

$$P ( Q ( t ) ) = α ⨯ {\{ Q ( t ) \}}^{3} + β ⨯ {\{ Q ( t ) \}}^{2} + γ ⨯ Q ( t ) + δ \qquad expression 21$$

(4) The time correction amount estimation unit 2077 calculates the time correction amount, learns the pattern of time-frequency deviation characteristics P(C(t)) corresponding to the time correction amount, and uses the pattern of the time-frequency deviation characteristics P(C(t)) for sign detection. Information used for sign detection is similar to those described in (2-a) of Embodiment 2.

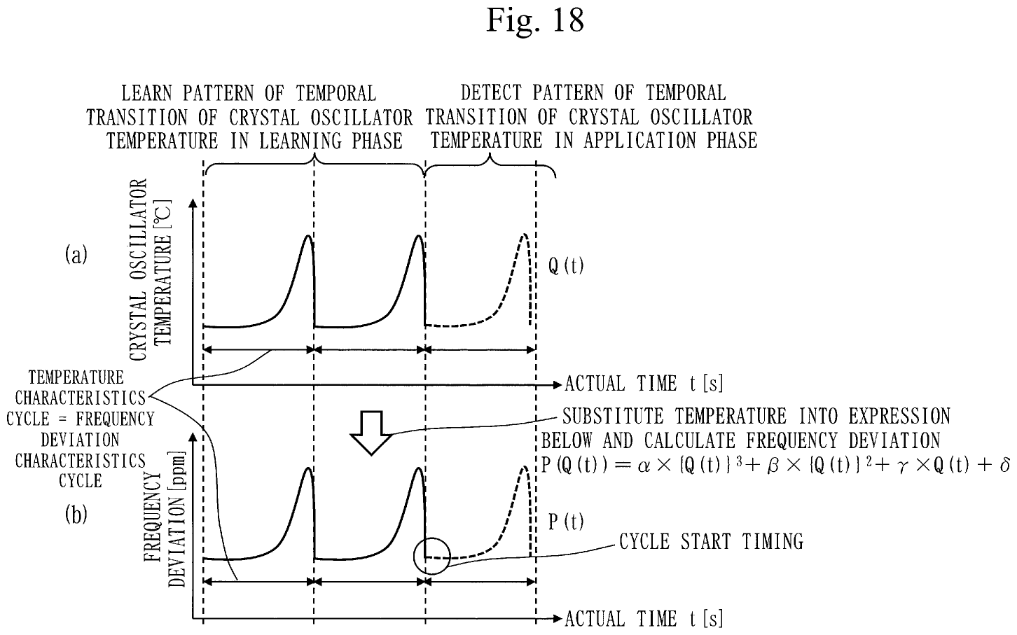

FIG. 18 represents the relationship between the temporal transition of the crystal oscillator temperature and the temporal transition of frequency deviation which have periodicity. The graph in (a) of FIG. 18 represents the temporal transition of the temperature of the crystal oscillator. With the expression of P(Q(t)) (expression 21), the relationship between temperature and time shown in (a) of FIG. 18 can be converted into the relationship between frequency deviation and temporal transition, as the graph in (b) of FIG. 18.

Then, the time correction amount estimation unit 2077 learns the frequency deviation characteristics cycle and the start timing of the frequency deviation characteristics cycle like FIG. 18, and uses the frequency deviation characteristics cycle and the start timing of the frequency deviation characteristics cycle in sign detection.

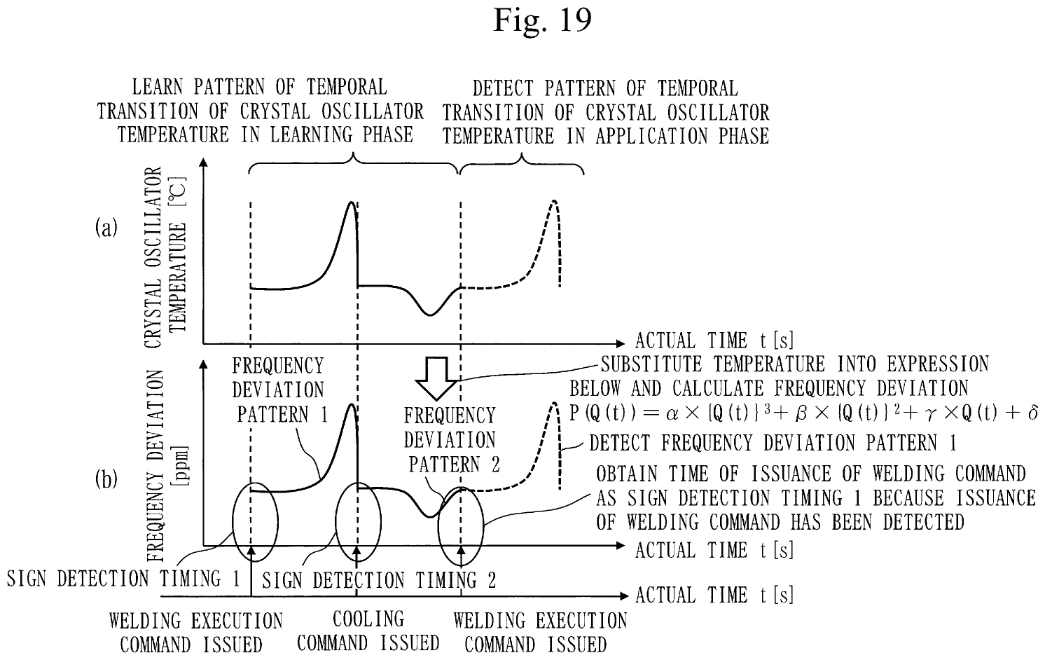

Alternatively, as in (2-b) of Embodiment 2, the time correction amount estimation unit 2077 learns the frequency deviation pattern and the sign detection timing like FIG. 19, and uses the frequency deviation pattern and the sign detection timing in sign detection.

FIG. 19 represents the relationship between the temporal transition of the crystal oscillator temperature and the temporal transition of frequency deviation when various kinds of commands are issued. The graph in (a) of FIG. 19 represents the temporal transition of the temperature of the crystal oscillator. With the expression of P(Q(t)) (expression 21), the relationship between temperature and time shown in (a) of FIG. 19 can be converted into the relationship between frequency deviation and temporal transition, as the graph in (b) of FIG. 19. In FIG. 19, there are two frequency deviation patterns and their sign detection timings are the time of issuance of a welding execution command and the time of issuance of a cooling command, respectively. In the application phase in the example of FIG. 19, the deviation temporal characteristics estimation unit 2076 detects the time of issuance of a welding execution command and the time of issuance of a cooling command as sign detection timings, and inputs the sign detection timings to the time correction amount estimation unit 2077.

While the specific example shown in FIG. 19 uses deviation temporal characteristics as converted from temperature information for sign detection, the temporal transition of the crystal oscillator temperature may also be used in sign detection without converting the temperature information into deviation temporal characteristics.

****Application Phase****

(3-a)

The deviation temporal characteristics estimation unit 2076 detects that the frequency deviation has the frequency deviation pattern of FIG. 18 from the input crystal oscillator temperature and the time information of the time at which the temperature was observed. Then, the deviation temporal characteristics estimation unit 2076 indicates the frequency deviation pattern, frequency deviation characteristics cycle, and cycle start timing to the time correction amount estimation unit 2077.

The time correction amount estimation unit 2077 indicates the time correction amount corresponding to the input frequency deviation pattern to the time correction unit 206.

The time correction unit 206 performs time correction with the indicated time correction amount.

While the present specific example uses deviation temporal characteristics as converted from temperature information for detection of a sign (deviation temporal characteristics), the temporal transition of crystal oscillator temperature may also be used in sign detection without converting the temperature information into deviation temporal characteristics.

(3-b)

The deviation temporal characteristics estimation unit 2076 detects that the frequency deviation has the frequency deviation pattern of FIG. 19 from the input crystal oscillator temperature, the time information of the time at which the temperature was observed, and control information. Then, the deviation temporal characteristics estimation unit 2076 indicates the frequency deviation pattern, frequency deviation characteristics cycle, and cycle start timing to the time correction amount estimation unit 2077.

The time correction amount estimation unit 2077 indicates the time correction amount corresponding to the input frequency deviation pattern to the time correction unit 206.

The time correction unit 206 performs time correction with the indicated time correction amount.

While the present specific example uses deviation temporal characteristics as converted from temperature information for detection of a sign (deviation temporal characteristics), the temporal transition of crystal oscillator temperature may also be used in sign detection without converting the temperature information into deviation temporal characteristics.

The above descriptions are given on an assumption that a crystal oscillator is used in the slave device 200. If an oscillator other than a crystal oscillator (for example, a silicon oscillator, a MEMS (Micro Electro Mechanical Systems) oscillator) is used with the slave device 200, the learning unit 207 learns the temperature characteristics of the appropriate oscillator.

As described above, the present embodiment also enables time correction in accordance with varying frequency deviation when the frequency deviation varies. Additionally, since time correction in the present embodiment is performed using a time correction amount resulting from learning, it does not require computation of frequency deviation change rate and time correction amount, allowing reduced computational burden.

### Embodiment 4

The present embodiment describes a configuration for selecting from the methods of time synchronization shown in Embodiment 1 to Embodiment 3 and performing the selected method of time synchronization.

In the present embodiment, mainly differences from Embodiment 1 to Embodiment 3 are discussed.

Matters that are not described below are similar to Embodiment 1 to Embodiment 3.

In the present embodiment, an exemplary configuration of the time synchronization system 1000 is also as shown in FIG. 1.

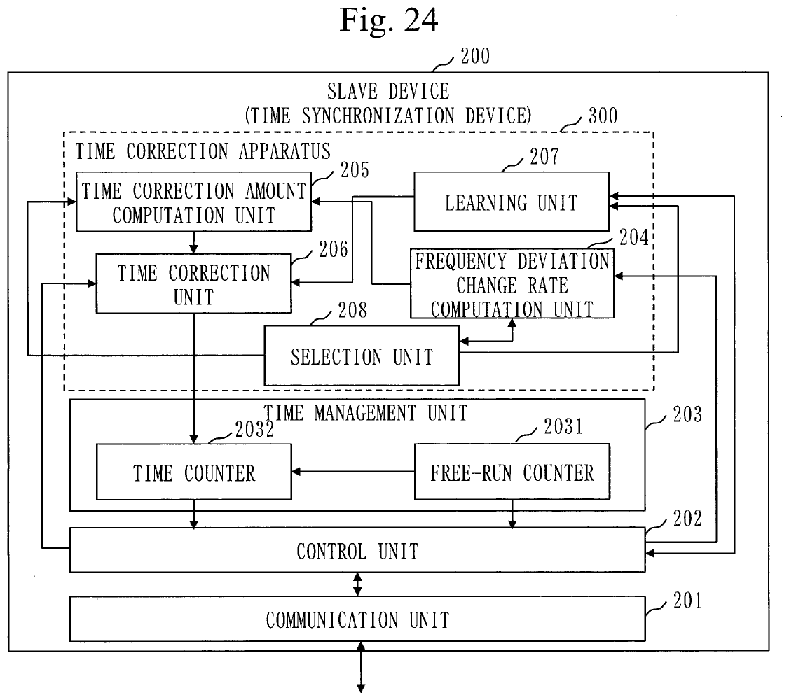

FIG. 24 shows a functional configuration example of the slave device 200 according to the present embodiment.

An exemplary hardware configuration of the slave device 200 according to the present embodiment is as shown in FIG. 2. The functions of a selection unit 208, discussed later, are also implemented by a program and the program for implementing the functions of the selection unit 208 is also executed by the processor 901.

Compared to FIG. 6, the selection unit 208 has been added in FIG. 24. The other elements of FIG. 24 are the same as those shown in FIG. 6.

In the present embodiment, the frequency deviation change rate computation unit 204, the time correction amount computation unit 205, the time correction unit 206, the learning unit 207, and the selection unit 208 correspond to the time correction apparatus 300.

The selection unit 208 monitors, in a method selecting phase, the frequency deviation change rate computed by the frequency deviation change rate computation unit 204 for a monitoring period. Then, depending on the frequency deviation change rate in the monitoring period, the selection unit 208 selects one of the time correction method described in Embodiment 1, the time correction method (2-a) described in Embodiment 2, the time correction method (2-b) described in Embodiment 2, and the time correction method described in Embodiment 3.

In the following, the time correction method described in Embodiment 1 will be referred to as time correction method (1). The time correction method described in Embodiment 3 will be referred to as time correction method (3).

When the frequency deviation change rate has transitioned below a threshold value 1 during the monitoring period, the selection unit 208 selects the time correction method (1), for example.

When the frequency deviation change rate has transitioned at or above the threshold value 1 and below a threshold value 2 during the monitoring period, the selection unit 208 selects the time correction method (2-a) or the time correction method (2-b), for example.

When the frequency deviation change rate has been above the threshold value 2 during the monitoring period, the selection unit 208 selects the time correction method (3), for example.

The criterion for the selection unit 208 to select a time correction method is not limited to the foregoing. The selection unit 208 can select a time correction method in accordance with a selection criterion other than the foregoing.

When selecting the time correction method (1), the selection unit 208 instructs the frequency deviation change rate computation unit 204 to compute the frequency deviation change rate and instructs the time correction amount computation unit 205 to compute the time correction amount.

When selecting the time correction method (2-a), the selection unit 208 instructs the learning unit 207 to perform the learning of the time correction method (2-a) described in Embodiment 2 and compute the time correction amount.

When selecting the time correction method (2-b), the selection unit 208 instructs the learning unit 207 to perform the learning of the time correction method (2-b) described in Embodiment 2 and compute the time correction amount.

When selecting the time correction method (3), the selection unit 208 instructs the learning unit 207 to perform the learning of the time correction method (3) and compute the time correction amount.

According to the present embodiment, an appropriate time correction method can be selected according to the level of the frequency deviation change rate.

Time correction with IEEE802.1AS or IEEE1588 may be added as an option for selecting the time correction method by the selection unit 208.

### Embodiment 5

The present embodiment describes an example where the time correction apparatus 300 is separated between the slave device 200 and a server device 400.

In the present embodiment, mainly differences from Embodiment 2 and Embodiment 3 are discussed.

Matters that are not described below are similar to Embodiment 2 and Embodiment 3.

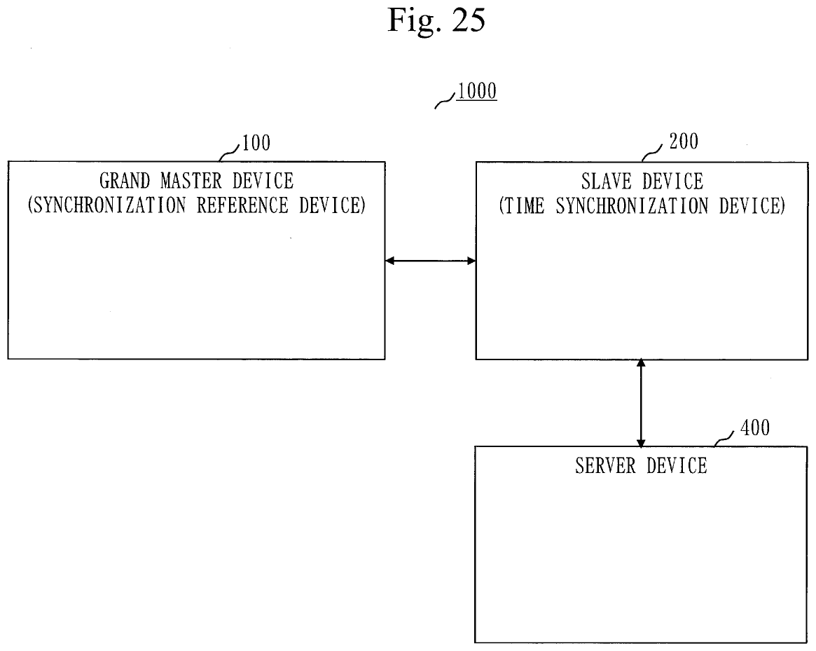

FIG. 25 shows a configuration example of the time synchronization system 1000 according to the present embodiment.

In FIG. 25, the server device 400 has been added compared to FIG. 1.

In the present embodiment again, the grand master device 100 corresponds to the synchronization reference device and the slave device 200 corresponds to the time synchronization apparatus.

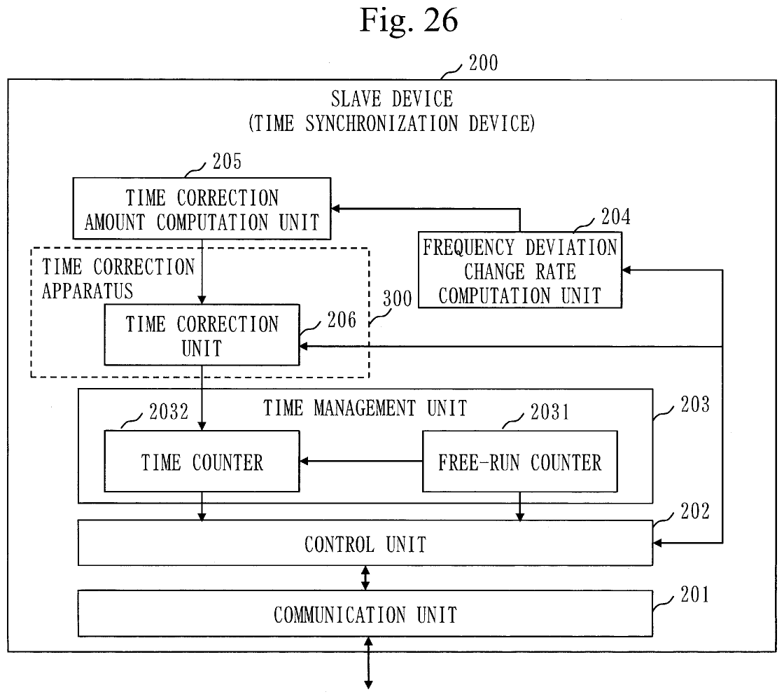

FIG. 26 shows a functional configuration example of the slave device 200 according to the present embodiment.

While the functional configuration example of FIG. 26 is the same as that shown in FIG. 3, in the present embodiment the frequency deviation change rate computation unit 204 indicates a computed frequency deviation change rate to the control unit 202. The control unit 202 indicates the frequency deviation change rate indicated from the frequency deviation change rate computation unit 204 to the server device 400 via the communication unit 201. The communication unit 201 receives a time correction amount computed on the server device 400 from the server device 400. The communication unit 201 indicates the received time correction amount to the control unit 202. The control unit 202 indicates the indicated time correction amount to the time correction unit 206. The time correction unit 206 performs time correction using the time correction amount indicated from the control unit 202.

In the present embodiment, the time correction unit 206 and a learning unit 402, to be discussed later, correspond to the time correction apparatus 300.

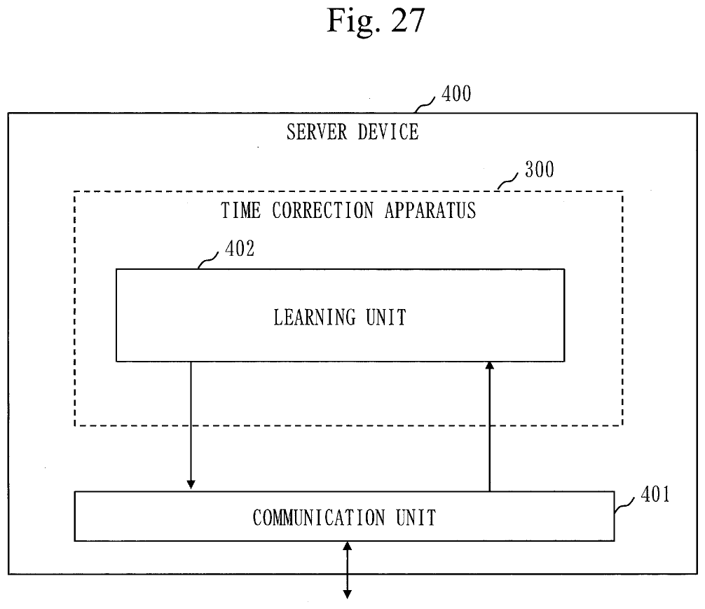

FIG. 27 shows a functional configuration example of the server device 400.

A communication unit 401 performs communications with the slave device 200.

Specifically, the communication unit 401 receives a frequency deviation change rate from the slave device 200 and indicates the received frequency deviation change rate to the learning unit 402.

The communication unit 401 also transmits a time correction amount computed by the learning unit 402 to the slave device 200.

The learning unit 402 has similar functions to those of the learning unit 207 described in Embodiment 2 and Embodiment 3.

That is, the learning unit 402 performs the operations in the learning phase of the time correction methods (2-a) and (2-b) described in Embodiment 2, using the frequency deviation change rate indicated from the communication unit 401, and computes a time correction amount. When the learning unit 402 performs the operations in the learning phase of the time correction method (2-b), the control unit 202 of the slave device 200 indicates to the learning unit 402, an event that can be a sign (such as the issuance of a welding execution command and the issuance of a cooling command in FIG. 12) together with the frequency deviation change rate.

The learning unit 402 performs the operations in the learning phase of the time correction method (3) described in Embodiment 3, using the frequency deviation change rate indicated from the communication unit 401, and computes a time correction amount. When the learning unit 402 performs the operations in the learning phase of the time correction method (3), the control unit 202 of the slave device 200 indicates, to the learning unit 402, the temperature characteristics of the crystal oscillator in the slave device 200 together with the frequency deviation change rate.

The learning unit 402 transmits the computed time correction amount to the slave device 200 via the communication unit 401. When the learning unit 402 has performed the operation in the learning phase of the time correction method (2-a), the start timing of the frequency deviation pattern is also transmitted to the slave device 200 via the communication unit 401. When the learning unit 402 has performed the operation in the learning phase of the time correction method (2-b), the sign detection timing is also transmitted to the slave device 200 via the communication unit 401.

As noted above, in the present embodiment, the time correction unit 206 and the learning unit 402 correspond to the time correction apparatus 300.

As described above, time correction in accordance with varying frequency deviation is possible also in a case where the time correction amount is learned at the server device as in the present embodiment.

While Embodiment 1 to Embodiment 5 have been described, two or more of the embodiments may be practiced in combination.

Alternatively, one of the embodiments may be partially practiced.

Alternatively, two or more of the embodiments may be practiced in partial combination.

Also, the configurations and procedures described in the embodiments may be modified as needed.

***Supplementary Description of Hardware Configuration***

Finally, supplementary description on the hardware configuration of the slave device 200 is provided.

The processor 901 shown in FIG. 2 is an IC (Integrated Circuit) that performs processing.

The processor 901 is a CPU (Central Processing Unit), a DSP (Digital Signal Processor), and the like.

The main storage device 902 shown in FIG. 2 is a RAM (Random Access Memory).

The auxiliary storage device 903 shown in FIG. 2 is a ROM (Read Only Memory), a flash memory, an HDD (Hard Disk Drive), and the like.

The communication device 904 shown in FIG. 2 is an electronic circuit that executes data communication processing.

The communication device 904 is a communications chip or a NIC (Network Interface Card), for example.

The auxiliary storage device 903 has also stored an OS (Operating System) therein.

At least part of the OS is then executed by the processor 901.

While executing at least part of the OS, the processor 901 executes programs for implementing the functions of the communication unit 201, the control unit 202, the time management unit 203, the frequency deviation change rate computation unit 204, the time correction amount computation unit 205, the time correction unit 206, the learning unit 207, and the selection unit 208.

By the processor 901 executing the OS, task management, memory management, file management, communication control, and the like are performed.

At least any of information, data, signal values, and variable values indicative of results of processing by the communication unit 201, the control unit 202, the time management unit 203, the frequency deviation change rate computation unit 204, the time correction amount computation unit 205, the time correction unit 206, the learning unit 207, and the selection unit 208 is stored in at least any of the main storage device 902, the auxiliary storage device 903, and a register and cache memory in the processor 901.

The programs for implementing the functions of the communication unit 201, the control unit 202, the time management unit 203, the frequency deviation change rate computation unit 204, the time correction amount computation unit 205, the time correction unit 206, the learning unit 207, and the selection unit 208 may also be stored on a mobile recording medium such as a magnetic disk, flexible disk, optical disk, compact disk, and Blu-ray (registered trademark) disk, and DVD. Then, the mobile recording media storing the programs for implementing the functions of the communication unit 201, the control unit 202, the time management unit 203, the frequency deviation change rate computation unit 204, the time correction amount computation unit 205, the time correction unit 206, the learning unit 207, and the selection unit 208 may be distributed.

The “units” of the communication unit 201, the control unit 202, the time management unit 203, the frequency deviation change rate computation unit 204, the time correction amount computation unit 205, the time correction unit 206, the learning unit 207, and the selection unit 208 may be read as “circuit” or “step” or “procedure” or “process”.

The slave device 200 may be implemented by a processing circuit. The processing circuit can be a logic IC (Integrated Circuit), a GA (Gate Array), an ASIC (Application Specific Integrated Circuit), or an FPGA (Field-Programmable Gate Array), for example.

In the present specification, a superordinate concept of processor and processing circuit is referred to as “processing circuitry”.

That is to say, processor and processing circuit are each a specific example of “processing circuitry”.

### REFERENCE SIGNS LIST

100: grand master device; 200: slave device; 201: communication unit; 202: control unit; 203: time management unit; 2031: free-run counter; 2032: time counter; 204: frequency deviation change rate computation unit; 205: time correction amount computation unit; 206: time correction unit; 207: learning unit; 2071: deviation temporal characteristics estimation unit; 2072: time correction amount estimation unit; 2075: deviation temperature characteristics estimation unit; 2076: deviation temporal characteristics estimation unit; 2077: time correction amount estimation unit; 208: selection unit; 300: time correction apparatus; 400: server device; 401: communication unit; 402: learning unit; 901: processor; 902: main storage device; 903: auxiliary storage device; 904: communication device; 1000: time synchronization system

1. A time correction apparatus comprising:
processing circuitry
to compute a frequency deviation change rate being a change rate per unit time of a frequency deviation between a clock frequency of a synchronization reference device serving as a reference of time synchronization and a clock frequency of a time synchronization device which performs time synchronization with the synchronization reference device;
to compute a first correction amount corresponding to a static frequency deviation between the clock frequency of the synchronization reference device and the clock frequency of the time synchronization device, to perform time integration of the frequency deviation change rate to compute a second correction amount corresponding to temporal transition of the frequency deviation between the clock frequency of the synchronization reference device and the clock frequency of the time synchronization device, and to compute a time correction amount for correcting a time of the time synchronization device with using the first correction amount and the second correction amount; and
to correct the time of the time synchronization device with using the time correction amount.

2. The time correction apparatus according to claim 1, wherein
the processing circuitry corrects the time of the time synchronization device by subtracting the time correction amount from a time counter of the time synchronization device.

3. The time correction apparatus according to claim 1, wherein
the processing circuitry
computes the frequency deviation change rate in accordance with a time synchronization frame transmission interval being an interval at which the synchronization reference device transmits a time synchronization frame for time synchronization to the time synchronization device,
computes the first correction amount and the second correction amount in accordance with the time synchronization frame transmission interval, and
computes the time correction amount for a current time synchronization frame transmission interval with using the first correction amount and the second correction amount that have been computed in the time synchronization frame transmission interval immediately preceding the current time synchronization frame transmission interval.

4. The time correction apparatus according to claim 1, wherein
the processing circuitry selects whether to use a time correction amount computed by machine learning or use the time correction amount computed.

5. The time correction apparatus according to claim 4, wherein
when using the time correction amount computed by the machine learning, the processing circuitry further selects which one of a plurality of machine learning methods is used to compute the time correction amount to be used.

6. A time correction apparatus comprising:
processing circuitry
to, in a learning phase, learn temporal transition of a frequency deviation between a clock frequency of a synchronization reference device serving as a reference of time synchronization and a clock frequency of a time synchronization device which performs time synchronization with the synchronization reference device, to extract a pattern of the temporal transition of the frequency deviation as a frequency deviation pattern, to compute a frequency deviation change rate in the frequency deviation pattern, and to perform time integration of a product of the frequency deviation change rate and time and the frequency deviation at a predefined timing to compute a time correction amount for correcting a time of the time synchronization device; and
to correct the time of the time synchronization device with using the time correction amount, in an application phase.

7. The time correction apparatus according to claim 6, wherein
the processing circuitry
in the learning phase, estimates a start timing of the frequency deviation pattern as the predefined timing, and performs time integration of the product of the frequency deviation change rate and time and the frequency deviation at the start timing of the frequency deviation pattern to compute the time correction amount, and
corrects the time of the time synchronization device with using the time correction amount, in the application phase, when the start timing of the frequency deviation pattern has arrived.

8. The time correction apparatus according to claim 6, wherein
the processing circuitry
in the learning phase, extracts a pattern of temporal transition having a sharp change in the frequency deviation change rate as the frequency deviation pattern, estimates a sign that occurs before the frequency deviation pattern occurs, estimates a detection timing of the sign as the predefined timing, and performs time integration of the product of the frequency deviation change rate and time and the frequency deviation at the detection timing of the sign to compute the time correction amount, and
corrects the time of the time synchronization device with using the time correction amount, in the application phase, when the sign is detected.

9. The time correction apparatus according to claim 6, wherein
the processing circuitry
in the learning phase, learns temperature characteristics with an oscillator that is used for generation of clocks of the synchronization reference device and computes the time correction amount adapted for the temperature characteristics, and
corrects the time of the time synchronization device with using the time correction amount adapted for the temperature characteristics, in the application phase.

10. A time correction method comprising:
computing a frequency deviation change rate being a change rate per unit time of a frequency deviation between a clock frequency of a synchronization reference device serving as a reference of time synchronization and a clock frequency of a time synchronization device which performs time synchronization with the synchronization reference device;
computing a first correction amount corresponding to a static frequency deviation between the clock frequency of the synchronization reference device and the clock frequency of the time synchronization device, performing time integration of the frequency deviation change rate to compute a second correction amount corresponding to temporal transition of the frequency deviation between the clock frequency of the synchronization reference device and the clock frequency of the time synchronization device, and computing a time correction amount for correcting a time of the time synchronization device with using the first correction amount and the second correction amount; and
correcting the time of the time synchronization device with using the time correction amount.

11. A time correction method comprising:
in a learning phase, learning temporal transition of a frequency deviation between a clock frequency of a synchronization reference device serving as a reference of time synchronization and a clock frequency of a time synchronization device which performs time synchronization with the synchronization reference device, extracting a pattern of the temporal transition of the frequency deviation as a frequency deviation pattern, computing a frequency deviation change rate in the frequency deviation pattern, and performing time integration of a product of the frequency deviation change rate and time and the frequency deviation at a predefined timing to compute a time correction amount for correcting a time of the time synchronization device; and
correcting the time of the time synchronization device with using the time correction amount, in an application phase.

12. A non-transitory computer readable medium storing a time correction program that causes a computer to execute:
a frequency deviation change rate computation process of computing a frequency deviation change rate being a change rate per unit time of a frequency deviation between a clock frequency of a synchronization reference device serving as a reference of time synchronization and a clock frequency of a time synchronization device which performs time synchronization with the synchronization reference device;
a time correction amount computation process of computing a first correction amount corresponding to a static frequency deviation between the clock frequency of the synchronization reference device and the clock frequency of the time synchronization device, performing time integration of the frequency deviation change rate to compute a second correction amount corresponding to temporal transition of the frequency deviation between the clock frequency of the synchronization reference device and the clock frequency of the time synchronization device, and computing a time correction amount for correcting a time of the time synchronization device with using the first correction amount and the second correction amount; and
a time correction process of correcting the time of the time synchronization device with using the time correction amount.

13. A non-transitory computer readable medium storing a time correction program that causes a computer to execute:
a learning process of, in a learning phase, learning temporal transition of a frequency deviation between a clock frequency of a synchronization reference device serving as a reference of time synchronization and a clock frequency of a time synchronization device which performs time synchronization with the synchronization reference device, extracting a pattern of the temporal transition of the frequency deviation as a frequency deviation pattern, computing a frequency deviation change rate in the frequency deviation pattern, and performing time integration of a product of the frequency deviation change rate and time and the frequency deviation at a predefined timing to compute a time correction amount for correcting a time of the time synchronization device; and
a time correction process of correcting the time of the time synchronization device with using the time correction amount, in an application phase.
